(19) United States
(12) Patent Application Publication
(10) Pub. No.: US 2026/0190579 A1
(43) Pub. Date: Jul. 2, 2026

(54) DISPLAY PANEL AND ELECTRONIC DEVICE INCLUDING THE SAME

(71) Applicant: Samsung Display Co., Ltd., Yongin-si (KR)

(72) Inventors: Younjoo Lee, Yongin-si (KR); Kyungho Kim, Yongin-si (KR); Youngseok Seo, Yongin-si (KR)

(21) Appl. No.: 19/402,752

(22) Filed: Nov. 26, 2025

(30) Foreign Application Priority Data
Dec. 27, 2024 (KR) 10-2024-0199350

(51) Int. Cl. H10H 29/49

(52) U.S. Cl. CPC H10H 29/49

(57) ABSTRACT

An embodiment of the present disclosure provides a display panel including a plurality of first areas and a second area around each of the plurality of first areas. The display panel includes: a pixel circuit layer including a plurality of pixel circuits and insulating layers and provided in each of the plurality of first areas; a plurality of light-emitting diodes on the pixel circuit layer and electrically connected to each of the plurality of pixel circuits; a connection line provided in the second area and that electrically connects pixel circuits provided adjacent to each other among the plurality of pixel circuits; and an auxiliary pattern provided to cover both end portions of the connection line.

### CROSS-REFERENCE TO RELATED APPLICATION

The present application claims priority to and the benefit of Korean Patent Application No. 10-2024-0199350, filed on Dec. 27, 2024, in the Korean Intellectual Property Office, the entire content of which is hereby incorporated by reference.

### BACKGROUND

### 1. Field

Embodiments of the present disclosure relate to a display panel and an electronic device including the same.

### 2. Description of the Related Art

In general, with the development of display devices that visually display electrical signals, there have been introduced various display panels having excellent properties such as thinness, lightness, and low power consumption, and electronic devices including the same. For example, display panels having various structures, such as flexible display panels or stretchable display panels, which can be folded and/or rolled into a roll shape, and electronic devices including the same, are actively being researched and developed.

### SUMMARY

Embodiments of the present disclosure provide a display panel that has improved stretchability and implements excellent quality images even if (e.g., when) stretched, and an electronic device including the same. However, such an objective is an example, and the scope of the present disclosure is not limited thereby.

An embodiment of the present disclosure provides a display panel including a plurality of first areas and a second area around (e.g., surrounding) each of the plurality of first areas. The display panel includes: a pixel circuit layer including a plurality of pixel circuits and insulating layers (e.g., electrically insulating layers) and arranged in each of the plurality of first areas; a plurality of light-emitting diodes on the pixel circuit layer and electrically connected to each of the plurality of pixel circuits; a connection line electrically connecting pixel circuits adjacent to each other among the plurality of pixel circuits; and an auxiliary pattern provided to cover both end portions (e.g., two opposing end portions) of the connection line.

In an embodiment, the both end portions of the connection line and the auxiliary pattern may be provided in one first area of the plurality of first areas, and a portion of the connection line, excluding the both end portions, may be provided in the second area.

In an embodiment, the modulus of the auxiliary pattern may be greater than the modulus of the connection line.

In an embodiment, the modulus of the auxiliary pattern may have a value in a range of 10 times to 5000 times the modulus of the connection line.

In an embodiment, the display panel may further include a base layer under the pixel circuit layer and that covers a lower surface of the connection line and a lower surface of the auxiliary pattern.

In an embodiment, with respect to the thickness direction of the pixel circuit layer, the thickness of the auxiliary pattern may be greater than the thickness of the connection line.

In an embodiment, with respect to the thickness direction of the pixel circuit layer, the thickness of the auxiliary pattern may be 1.25 times or more the thickness of the connection line.

In an embodiment, the connection line may extend in a first direction, the connection line may have a first width in a second direction that crosses the first direction, the auxiliary pattern may have a second width in the second direction, and in a plan view, the second width of the auxiliary pattern may be greater than the first width of the connection line.

In an embodiment, the second width of the auxiliary pattern may be 1.25 times or more the first width of the connection line.

In an embodiment, the connection line may include a plurality of connection lines, pixel circuits provided in one first area of the plurality of first areas may be connected to the plurality of connection lines, and the plurality of connection lines may include a plurality of horizontal connection lines that extend in a first direction and a plurality of vertical connection lines that extend in a second direction that crosses the first direction.

In an embodiment, the auxiliary pattern may be provided in plurality to respectively cover end portions of the plurality of connection lines, and the plurality of auxiliary patterns may be spaced apart from each other.

In an embodiment, one auxiliary pattern may cover end portions of two or more connection lines among the plurality of connection lines.

In an embodiment, one auxiliary pattern that covers all of end portions of the plurality of connection lines may be provided in one first area among the plurality of first areas.

In an embodiment, the auxiliary pattern may have a mesh pattern in the first area, in a plan view.

In an embodiment, the auxiliary pattern may have a single (e.g., sole) continuous shape to overlap the pixel circuit layer in a plan view.

In an embodiment, the auxiliary pattern may extend in the first area in a diagonal direction between the first direction and the second direction.

In an embodiment, one end of the auxiliary pattern may cover an end portion of one of the plurality of horizontal connection lines, and another end of the auxiliary pattern may cover an end portion of one of the plurality of vertical connection lines.

In an embodiment, the auxiliary pattern may extend in the first direction or the second direction, and may cover end portions of the plurality of connection lines provided on one side of the first area.

In an embodiment, the auxiliary pattern may be provided in plurality, some of the plurality of auxiliary patterns may cover an end portion of one connection line among the plurality of connection lines, and the rest of the plurality of auxiliary patterns may cover end portions of two or more connection lines among the plurality of connection lines.

In an embodiment, the auxiliary pattern may extend in the first direction, one end of the auxiliary pattern may cover an end portion of one of the plurality of horizontal connection lines provided on one side of the first area, and another end of the auxiliary pattern may cover an end portion of one of the plurality of horizontal connection lines provided on an opposite side to the one side.

Another embodiment of the present disclosure provides an electronic device including a display panel including a plurality of first areas and a second area around (e.g., surrounding) each of the plurality of first areas, and a lower cover that forms an exterior and having, in a front surface, an opening that exposes a portion of the display panel, wherein the display panel includes a pixel circuit layer including a plurality of pixel circuits and insulating layers (e.g., electrically insulating layers) and provided in each of the plurality of first areas, a plurality of light-emitting diodes on the pixel circuit layer and electrically connected to each of the plurality of pixel circuits, a connection line that electrically connects pixel circuits provided adjacent to each other among the plurality of pixel circuits, and an auxiliary pattern provided to cover both end portions of the connection line.

According to some embodiments of the present disclosure, a display panel that has improved stretchability and implements excellent quality images, and an electronic device including the same, may be provided. The effects described above are examples, and thus, the effects of embodiments of the present disclosure are not limited to the effects described above.

### BRIEF DESCRIPTION OF DRAWINGS

The accompanying drawings, together with the specification, illustrate embodiments of the subject matter of the present disclosure, and, together with the description, serve to explain principles of embodiments of the subject matter of the present disclosure.

FIG. 1A is a perspective view schematically showing an electronic device according to an embodiment of the present disclosure.

FIG. 1B is a block diagram schematically showing an electronic device according to an embodiment of the present disclosure.

FIG. 2 is a perspective view schematically showing a display panel according to an embodiment of the present disclosure.

FIGS. 3A and 3B are perspective views showing a state in which the display panel of FIG. 2 is stretched in a first direction.

FIG. 3C is a perspective view showing a state in which the display panel of FIG. 2 is stretched in a second direction.

FIG. 3D is a perspective view showing a state in which the display panel of FIG. 2 is stretched in the first direction and the second direction.

FIG. 3E is a perspective view showing a state in which the display panel of FIG. 2 is stretched in a third direction.

FIG. 4 is a plan view schematically showing a display panel according to an embodiment of the present disclosure.

FIG. 5 is a schematic plan view of an arrangement of pixels of a display panel according to an embodiment of the present disclosure.

FIG. 6 is a cross-sectional view schematically showing a portion of a display panel according to an embodiment of the present disclosure.

FIGS. 7A to 7C are each an equivalent circuit diagram of a pixel of a display panel according to an embodiment of the present disclosure.

FIGS. 8A to 8D are each a cross-sectional view schematically showing a light-emitting diode of a display panel according to an embodiment of the present disclosure.

FIG. 9 is a plan view schematically showing a portion of a display panel according to an embodiment of the present disclosure.

FIG. 10 is a plan view schematically showing a portion of a display panel according to an embodiment of the present disclosure.

FIG. 11 is a cross-sectional view schematically showing a portion of a display panel according to an embodiment of the present disclosure.

FIG. 12 is a perspective view showing an excerpt of a first line, a second line, a connection line, and an auxiliary pattern of FIG. 11.

FIGS. 13A to 13F are each a plan view schematically showing a portion of a display panel according to embodiments of the present disclosure.

FIGS. 14A to 14G are each a perspective view schematically showing embodiments of an electronic device including a display panel according to an embodiment of the present disclosure.

### DETAILED DESCRIPTION

Various suitable modifications may be applied to the subject matter of the present disclosure, and example embodiments will be illustrated in the drawings and described in the detailed description section. The effects and features of embodiments of the present disclosure, and methods to achieve the same, will be clearer referring to the detailed descriptions below with the drawings. However, embodiments of the present disclosure may be implemented in various suitable forms, and therefore, the present disclosure is not limited to the embodiments presented below.

Hereinafter, embodiments of the present disclosure will be described in more detail with reference to the accompanying drawings, and in the description with reference to the drawings, the same or corresponding constituents are indicated by the same reference numerals and redundant descriptions thereof may not be repeated.

In the following embodiments, although the terms first, second, and/or the like may be used herein to describe various elements, these elements should not be limited by these terms, but the elements are only used to distinguish one element from another.

In the following embodiments, as used herein, the singular forms are intended to include the plural forms as well, unless the context clearly indicates otherwise.

In the following embodiments, the terms comprises and/or comprising used herein specify the presence of stated features or elements in the specification, but do not preclude the presence or addition of one or more other features or components.

In the following embodiments, if (e.g., when) a portion, such as a film, a region, or an element, is referred to as being on another portion, the portion can be directly on the other portion or an intervening film, region, and/or element may be present thereon.

Sizes of elements in the drawings may be exaggerated for convenience of explanation. For example, because sizes and thicknesses of elements in the drawings may be arbitrarily illustrated for convenience of explanation, the present disclosure is not limited thereto.

If (e.g., when) an embodiment may be implemented differently, a specific process order may be performed differently from the described order. For example, two consecutively described processes may be performed substantially at the same time or performed in an order opposite to the described order.

In the following embodiments, if (e.g., when) a film, a region, or an element is referred to as being connected to another film, region, or element, it can be directly connected to the other film, region, or element or indirectly connected to the other film, region, or element via intervening films, regions, and/or elements. For example, in the following embodiment, if (e.g., when) a film, a region, or an element is referred to as being electrically connected to another film, region, or element, it can be directly electrically connected to the other film, region, or element or indirectly electrically connected to the other film, region, or element via intervening films, regions, and/or elements.

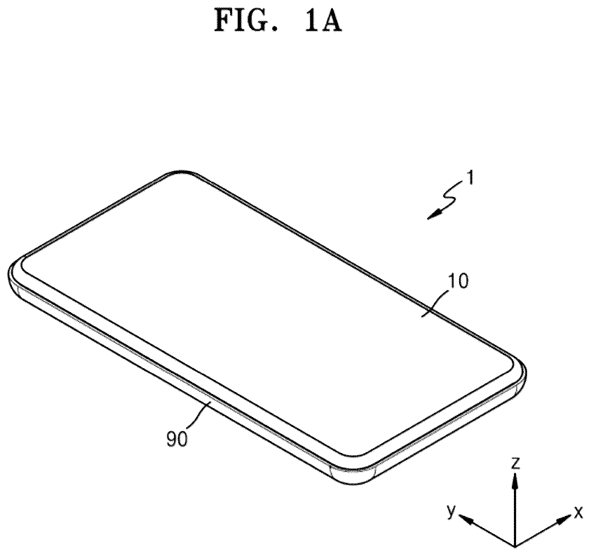

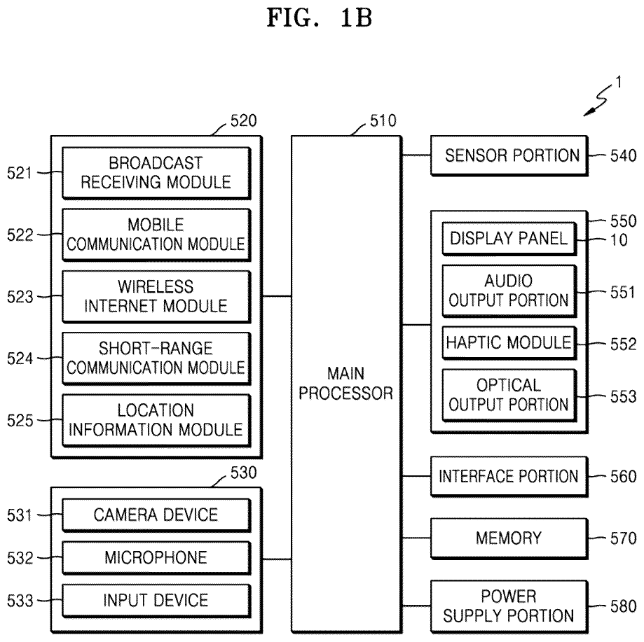

FIG. 1A is a perspective view schematically showing an electronic device 1 according to an embodiment of the present disclosure. FIG. 1B is a block diagram schematically showing the electronic device 1 according to an embodiment of the present disclosure.

Referring to FIGS. 1A and 1B, the electronic device 1 including a display panel 10 according to an embodiment of the present disclosure, which is a device to display a video and/or a still image, may be used as a display screen not only for portable electronic devices, such as a mobile phone, a smart phone, a tablet personal computer (PC), a mobile communication terminal, an electronic organizer, an electronic book, a portable multimedia player (PMP), a navigation device, an ultra-mobile PC (UMPC), and/or the like, but also for various suitable products, such as a television, a notebook computer, a monitor, a billboard, the Internet of things (IOT), and/or the like. The electronic device 1 according to an embodiment may be used for wearable devices, such as a smart watch, a watch phone, a glasses-type display, and/or a head mounted display (HMD). The electronic device 1 according to an embodiment may be used as an instrument panel of a vehicle, a center information display (CID) provided at the center fascia and/or dashboard of a vehicle, a room mirror display in lieu of a side mirror of a vehicle, and/or a display screen provided at the rear surface of a front seat as an entertainment device for a rear seat of a vehicle.

FIG. 1A illustrates that the electronic device 1 according to an embodiment is used as a smart phone. The electronic device 1 may include the display panel 10 and a lower cover 90 disposed under the display panel 10. The electronic device 1 may include a cover window that covers the upper surface of the display panel 10.

The lower cover 90 may form the exterior of the electronic device 1 and may have an opening at the front surface thereof to expose a portion of the display panel 10. The lower cover 90 having a shape in which a surface corresponding to the display panel 10 is open may be assembled with the display panel 10. The lower cover 90 may form the exterior of the lower surface of the electronic device 1, and a display circuit board, a component, a main circuit board, a battery, a driver, and/or the like may be between the display panel 10 and the lower cover 90. The lower cover 90 may include plastic (e.g., polymer), metal, and/or both of plastic (e.g., polymer) and metal.

The electronic device 1 may include a main processor 510, a wireless communication portion 520, an input portion 530, a sensor portion 540, an output portion 550, an interface portion 560, a memory 570, and/or a power supply portion 580.

The main processor 510 may control all (or substantially all) functions of the electronic device 1. For example, the main processor 510 may output digital video data to a data driver through a display circuit board so that the display panel 10 may display an image. The main processor 510 may receive detection data from a touch sensor driving portion. The main processor 510 may determine the presence of a user's touch according to the detection data, and perform an operation corresponding to a user's direct touch or proximity touch. The main processor 510 may be an application processor, a central processing unit, and/or a system chip, which includes an integrated circuit.

A camera device 531 may process image frames, such still images, videos, and/or the like, which are obtained by an image sensor in a camera mode, and output the processed image frames to the main processor 510. The camera device 531 may include at least one selected from a camera sensor (e.g., CCD, CMOS, and/or the like), a photo sensor (or an image sensor), and a laser sensor. The camera device 531 may be connected to the image sensor and may process an image input to the image sensor.

The wireless communication portion 520 may include at least one selected from a broadcast receiving module 521, a mobile communication module 522, a wireless Internet module 523, a short-range communication module 524, and a location information module 525.

The broadcast receiving module 521 may receive broadcast signals and/or broadcast-related information from an external broadcast management server through a broadcast channel. The broadcast channel may include a satellite channel and a terrestrial channel.

The mobile communication module 522 may transceive wireless signals with at least one selected from a base station, an external terminal, and a server on a mobile communication network established according to technical standards and/or communication protocols for mobile communications (e.g., global system for mobile communication (GSM), code division multi access (CDMA), code division multi access 2000(CDMA2000 ), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), and/or the like). The wireless signals may include various suitable types or kinds of data according to transceiving of a voice call signal, a video call signal, and/or a text/multimedia message.

The wireless Internet module 523 may denote a module for wireless Internet connection. The wireless Internet module 523 may be configured to transceive wireless signals on a communication network according to the wireless Internet technologies. The wireless Internet technologies may include, for example, wireless LAN (WLAN), wireless-fidelity (Wi-Fi), Wi-Fi Direct, digital living network alliance (DLNA), and/or the like.

The short-range communication module 524 may be for short-range communication, and may support short-range communication by using at least one selected from Bluetooth (Bluetooth™), radio frequency identification (RFID), Infrared Communication Association (IrDA), ultra wideband (UWB), ZigBee, near field communication (NFC), Wi-Fi, Wi-Fi Direct, and wireless universal serial bus (USB) technologies. The short-range communication module 524 may support wireless communication between the electronic device 1 and a wireless communication system, between the electronic device 1 and another electronic device, and/or between the electronic device 1 and a network in which another electronic device (or an external server) is located, through a short-range wireless communication network (wireless area networks). The short-range wireless communication network may be a short-range wireless personal communication network (wireless personal area networks). The another electronic device may be a wearable device capable of exchanging data with the electronic device 1 (and/or operating in conjunction therewith).

The location information module 525, which is a module to obtain the location (and/or the current location) of the electronic device 1, may include a global positioning system (GPS) module and/or a WiFi module.

The input portion 530 may include an image input portion such as the camera device 531 for image signal input, an audio input portion such as a microphone 532 for audio signal input, and an input device 533 to receive information from a user.

The camera device 531 may process image frames such as a still image and/or a video obtained by the image sensor in a video call mode and/or an imaging mode. The processed image frames may be displayed on the display panel 10 and/or stored in the memory 570.

The microphone 532 processes external audio signals into electrical voice data. The processed voice data may be used in various suitable ways depending on a function (and/or a running application) performed in the electronic device 1.

The main processor 510 may control the operation of the electronic device 1 to correspond to the information input through the input device 533. The input device 533 may include a mechanical input device and/or a touch input device, such as a button, a dome switch, a jog wheel, a jog switch, and/or the like, placed at the rear surface and/or side surface of the electronic device 1. The touch input device may include a touchscreen layer of the display panel 10.

The sensor portion 540 may include one or more sensors that sense at least one selected from information within the electronic device 1, environment information around (e.g., surrounding) the electronic device 1, and user information, and generate a sensing signal corresponding thereto. The main processor 510 may control the driving and/or operation of the electronic device 1 based on the sensing signals, and/or perform data processing, functions, and/or operations related to an application installed in the electronic device 1. The sensor portion 540 may include at least one selected from a proximity sensor, an illumination sensor, an acceleration sensor, a magnetic sensor, a gravity (G)-sensor, a gyroscope sensor, a motion sensor, a red, green, and blue (RGB) sensor, an infrared (IR) sensor, a finger scan sensor, an ultrasonic sensor, an optical sensor, a battery gauge, an environment sensor (e.g., a barometer, a hygrometer, a thermometer, a radiation detection sensor, a heat detection sensor, a gas detection sensor, and/or the like), and a chemical sensor (e.g., an electronic nose, a healthcare sensor, a biometric sensor, and/or the like).

The output portion 550, which is to generate an output related to sight, hearing, touch, and/or the like, may include at least one selected from the display panel 10, an audio output portion 551, a haptic module 552, and an optical output portion 553.

The display panel 10 may display (output) the information processed in the electronic device 1. For example, the display panel 10 may display execution screen information of an application executed in the electronic device 1, and/or user interface (UI) and/or graphic user interface (GUI) information according to the execution screen information. The display panel 10 may include a display layer that displays an image and a touchscreen layer that detects a user′s touch input. Accordingly, while functioning as one input device 533 that provides an input interface between the electronic device 1 and the user, the display panel 10 may function as one output portion 550 that provides an output interface between the electronic device 1 and the user.

The audio output portion 551 may output audio data received from the wireless communication portion 520 and/or stored in the memory 570 in signal reception, a calling mode or recording mode, a voice recognition mode, a broadcast receiving mode, and/or the like. The audio output portion 551 may output an audio signal related to the function (e.g., call signal reception sound, message reception sound, and/or the like) performed in the electronic device 1. The audio output portion 551 may include a receiver and a speaker. At least one selected from the receiver and the speaker may be a sound generation device that is attached to a lower portion of the display panel 10 and outputs sound by vibrating the display panel 10. The sound generation device may be a piezoelectric element and/or a piezoelectric actuator that contracts and expands in response to an electrical signal, and/or an exciter that generates a magnetic force using a voice coil to vibrate the display panel 10.

The haptic module 552 generates various suitable tactile effects that users may feel. The haptic module 552 may provide a user with vibrations as a tactile effect. The haptic module 552 may be implemented not only to deliver tactile effects through direct contact, but also cause the user to feel the tactile effects through muscle sense, such as fingers and/or arms.

The optical output portion 553 output a signal to notify occurrence of an event by using light of a light source. Examples of the event occurring in the electronic device 1 may include message reception, call signal reception, missed calls, alarms, schedule reminders, email reception, information receiving via application, and/or the like. The signal output by the optical output portion 553 may be implemented as the electronic device 1 emits light of a single color and/or a plurality of colors to the front surface or the back surface. The signal output may be terminated as the electronic device 1 detects that the user checks an event.

The interface portion 560 performs as a path to various suitable types or kinds of external devices connected to the electronic device 1. The interface portion 560 may include at least one selected from a wired/wireless headset port, an external charger port, a wired/wireless data port, a memory card port, a port that connects a device having an identification module, an audio input/output (I/O) port, a video I/O port, and an earphone port. The electronic device 1 may perform, in response to the external device being connected to the interface portion 560, a suitable or appropriate control related to the connected external device.

The memory 570 stores data that supports various suitable functions of the electronic device 1. The memory 570 may store a plurality of applications (application programs) that run on the electronic device 1, pieces of data for the operation of the electronic device 1, and instructions. At least some of the plurality of applications may be downloaded from an external server through wireless communication. The memory 570 may store an application for the operation of the main processor 510, and/or temporarily store input/output data, for example, data, such as a phonebook, messages, still images, videos, and/or the like. Furthermore, the memory 570 may store haptic data for various suitable patterns of vibrations provided to the haptic module 552 and audio data for various suitable sounds provided to the audio output portion 551. The memory 570 may include a storage medium of at least one type or kind selected from a flash memory type or kind, a hard disk type or kind, a solid state disk (SSD) type or kind, a silicon disk drive (SDD) type or kind, a multimedia card micro type or kind, a card type memory (e.g., SD and/or XD memory, and/or the like), random access memory (RAM), static random access memory (SRAM), read-only memory (ROM), electrically erasable programmable read-only memory (EEPROM), programmable read-only memory (PROM), magnetic memory, a magnetic disk, and an optical disk.

The power supply portion 580, under the control of the main processor 510, receives external power and/or internal power and supplies power to each of components included in the electronic device 1. The power supply portion 580 may include a battery. Furthermore, the power supply portion 580 includes a connection port, and the connection port may be configured as an example of the interface portion 560 to which an external charger that supplies power to charge the battery is electrically connected. In embodiments, the power supply portion 580 may be configured to charge the battery in a wireless manner without using the connection port.

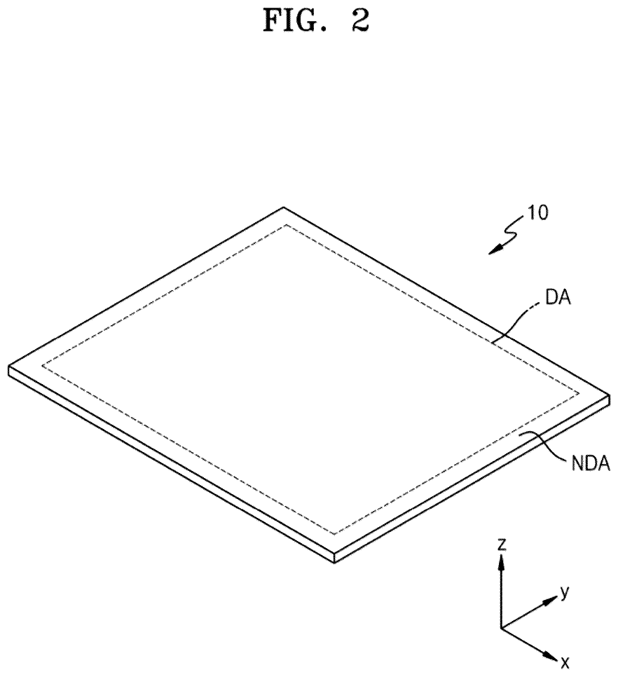

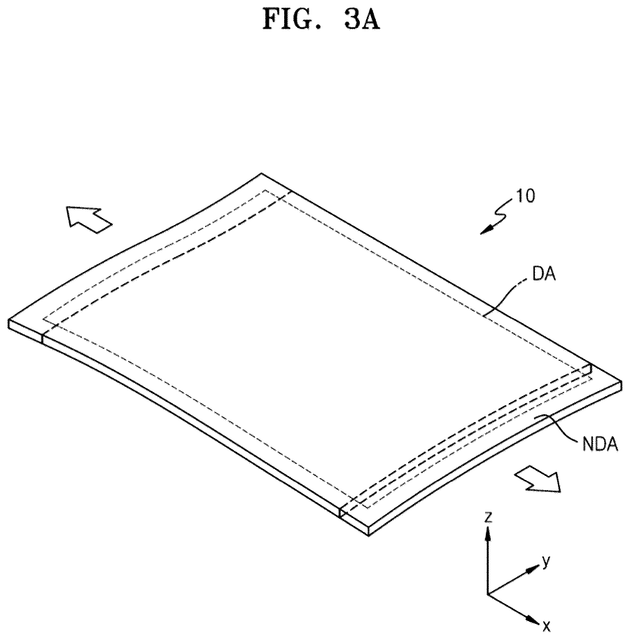

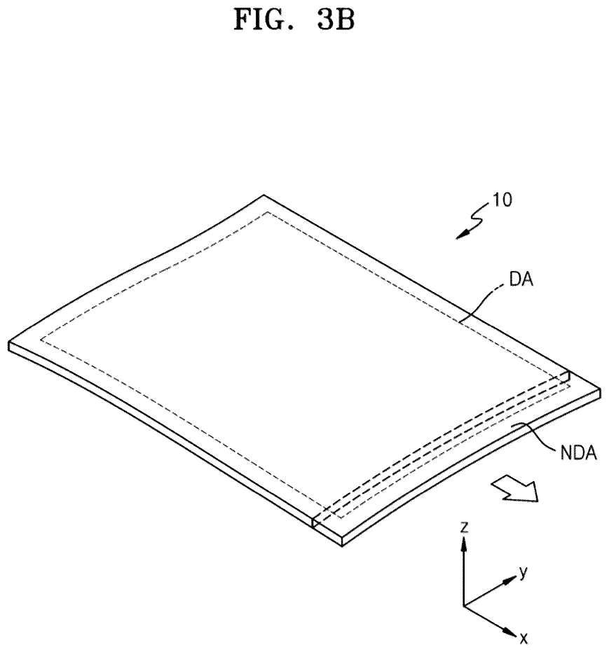

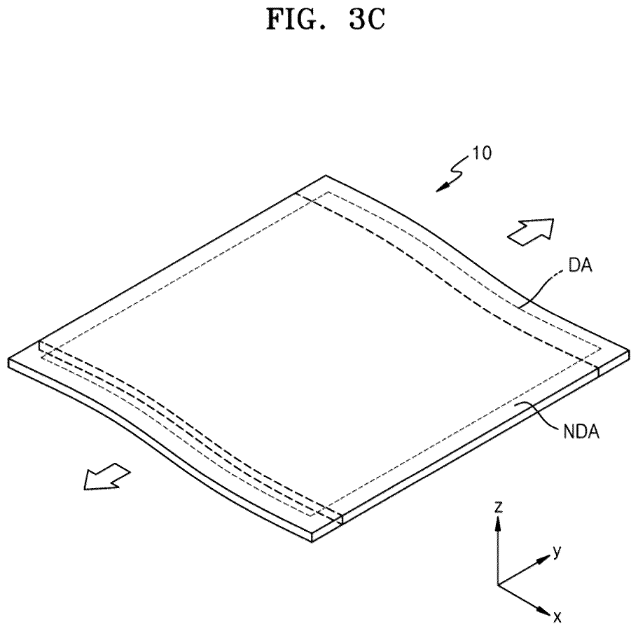

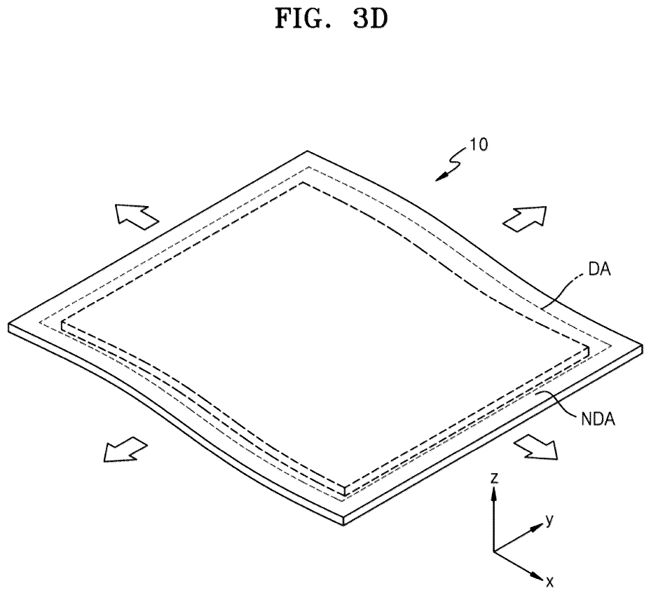

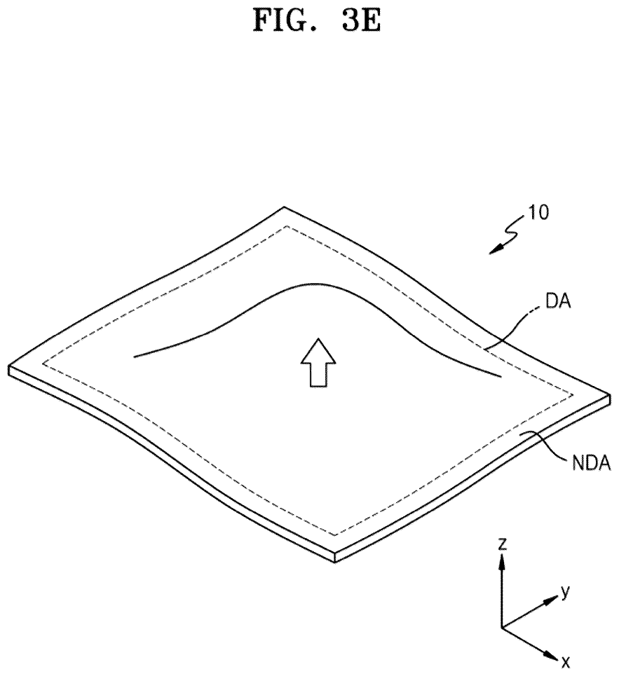

FIG. 2 is a schematic perspective view of the display panel 10 according to an embodiment. FIGS. 3A and 3B are perspective views showing a state in which the display panel 10 of FIG. 2 is stretched in a first direction. FIG. 3C is a perspective view showing a state in which the display panel 10 of FIG. 2 is stretched in a second direction. FIG. 3D is a perspective view showing a state in which the display panel 10 of FIG. 2 is stretched in both the first and second directions. FIG. 3E is a perspective view showing a state in which the display panel 10 of FIG. 2 is stretched in a third direction.

Referring to FIG. 2, the display panel 10 may include a display area DA and a non-display area NDA. The display area DA may include a plurality of pixels. The display panel 10 may provide a set or certain image by using light emitted from the plurality of pixels. The non-display area NDA may be provided outside the display area DA. The non-display area NDA may entirely surround the display area DA.

The display panel 10 may stretch and/or shrink in various suitable directions. The display panel 10 may be stretched in a first direction (e.g., an x direction and/or a −x direction) by an external force applied by an external object and/or a user. In an embodiment, as illustrated in FIGS. 3A and 3B, the display area DA and/or the non-display area NDA of the display panel 10 may be stretched in the first direction (e.g., the x direction and/or the −x direction). For example, the display area DA and/or the non-display area NDA of the display panel 10 may be stretched in the x direction and the −x direction, as illustrated in FIG. 3A, or may be stretched in the x direction with one side of the display panel 10 fixed, as illustrated in FIG. 3B.

The display panel 10 may be stretched in a second direction (e.g., a y direction and/or a −y direction) by an external force applied by an external object and/or a user. In an embodiment, as illustrated in FIG. 3C, the display area DA and/or the non-display area NDA of the display panel 10 may be stretched in the y direction and the −y direction. In another embodiment, the display area DA and/or the non-display area NDA of the display panel 10 may be stretched in the y direction or the −y direction with one side of the display panel 10 fixed.

The display panel 10 may be stretched by an external force applied by an external object and/or a part of a human body in a plurality of directions, for example, the first direction (e.g., the x direction and/or the −x direction) and in the second direction (e.g., the y direction and/or the −y direction). As illustrated in FIG. 3D, the display area DA and/or the non-display area NDA of the display panel 10 may be stretched in the ±x directions and the ±y directions.

The display panel 10 may be stretched in a third direction (e.g., a z direction or a −z direction) by an external force applied by an external object and/or a part of a human body. In an embodiment, FIG. 3E illustrates that a part of the display panel 10, for example, a partial area of the display area DA, protrudes in the z direction. In another embodiment, a part of the display panel 10, for example, a partial area of the display area DA may protrude in the z direction or may be recessed in the −z direction.

FIGS. 3A to 3E illustrate that the display device 1 is stretched in the first direction, the second direction, and/or the third direction, but the present disclosure is not limited thereto. In another embodiment, the display panel 10 may be transformed into various suitable amorphous shapes, such as bending and/or twisting about two or more axes.

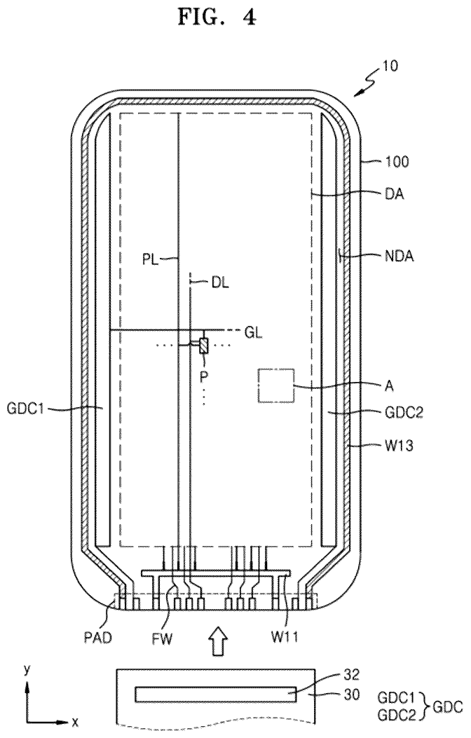

FIG. 4 is a plan view schematically showing the display panel 10 according to an embodiment of the present disclosure.

Referring to FIG. 4, the display panel 10 may include the display area DA and the non-display area NDA around (e.g., surrounding) the display area DA. Pixels P are provided in the display area DA of a substrate 100. The pixels P may each display an image by using light emitted from a light-emitting element such as a light-emitting diode. Each light-emitting diode may emit, for example, red, green, or blue light.

Each light-emitting diode may be electrically connected to a pixel circuit, and each pixel circuit may include transistors and a storage capacitor. Each of the pixel circuits may be electrically connected to peripheral circuits and peripheral wires provided in the non-display area NDA. The peripheral circuits provided in the non-display area NDA may include a gate drive circuit GDC and a terminal portion PAD. The peripheral wires may include a driving voltage supply wire W11, a common voltage supply wire W13, and a fan-out wire FW.

The gate drive circuit GDC may include drivers to provide electrical signals to a gate electrode of each of the transistors electrically connected to the light-emitting elements. In more detail, the gate drive circuit GDC may apply a scan signal to each of the pixel circuits corresponding to the pixels P through a gate line GL.

The gate drive circuit GDC may include a first gate drive circuit GDC1 and a second gate drive circuit GDC2 which are on the opposite sides with the display area DA therebetween. The second gate drive circuit GDC2 may be provided at the opposite side to the first gate drive circuit GDC1 with respect to the display area DA, and may be approximately parallel to the first gate drive circuit GDC1. While some of the pixel circuits may be electrically connected to the first gate drive circuit GDC1, the other may be electrically connected to the second gate drive circuit GDC2. In some embodiments, the second gate drive circuit GDC2 may be omitted.

The terminal portion PAD may be provided at one side of the substrate 100. The terminal portion PAD may be connected to a display circuit board 30 without being covered by an insulating layer (e.g., an electrically insulating layer) so as to be exposed. A display driving portion 32 may be provided in the display circuit board 30. The display driving portion 32 may generate control signals transmitted to the first gate drive circuit GDC1 and the second gate drive circuit GDC2. The display driving portion 32 may generate data signals, and the generated data signals may be transmitted to the pixel circuit of each pixel P through the fan-out wire FW and a data line DL connected to the fan-out wire FW.

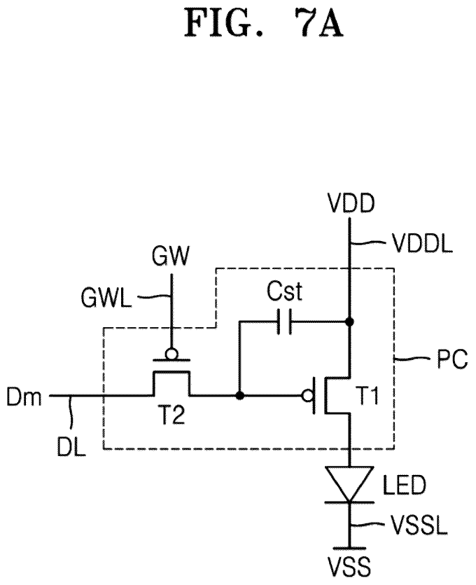

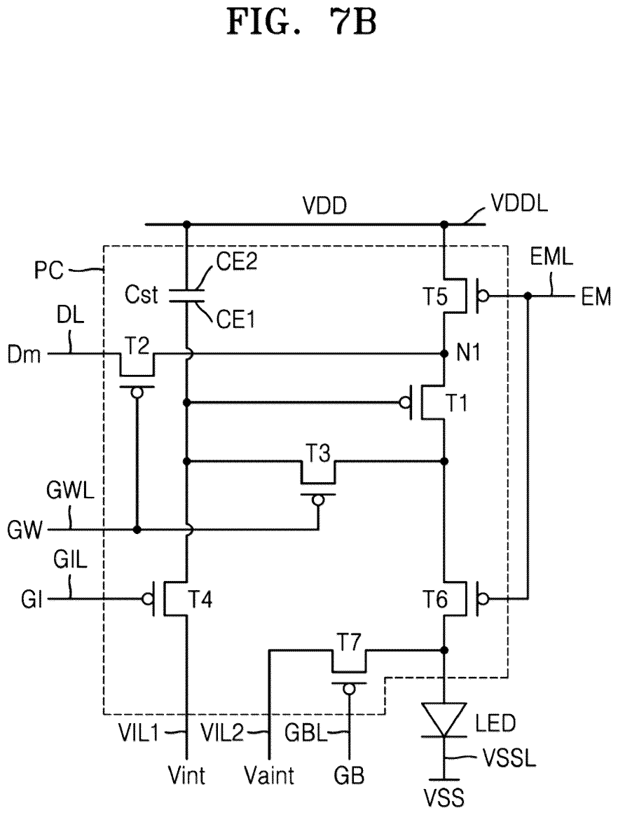

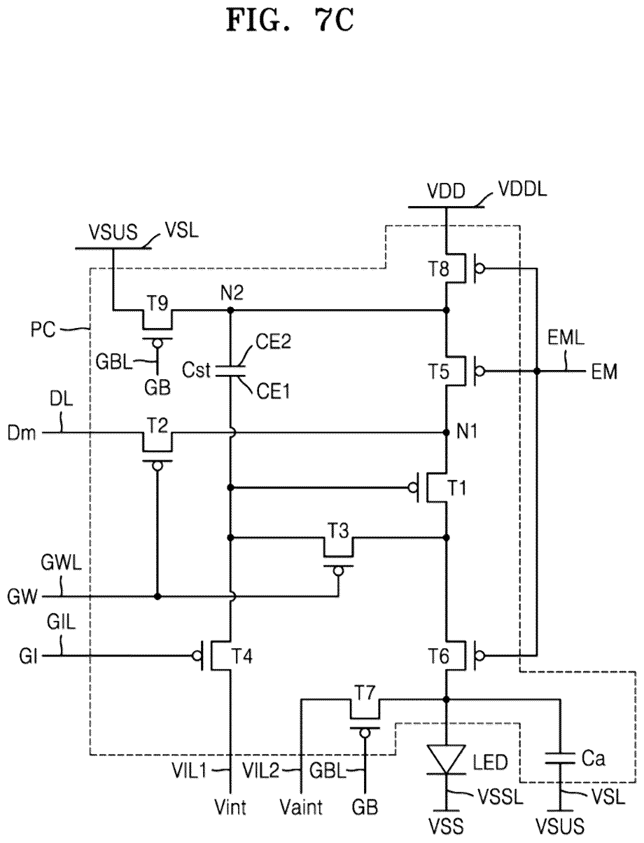

The display driving portion 32 may supply a first power voltage (VDD in FIG. 7A) to the driving voltage supply wire W11, and a second power voltage (VSS in FIG. 7A) to the common voltage supply wire W13. The first power voltage (VDD in FIG. 7A) may be applied to the pixel circuit of the pixel P through a driving voltage line PL connected to the driving voltage supply wire W11, and the second power voltage (VSS in FIG. 7A) may be connected to the common voltage supply wire W13 and applied to a counter electrode of the light-emitting element. The driving voltage supply wire W11 may be provided to extend in the x direction under the display area DA. The common voltage supply wire W13 having a loop shape having one open side may be partially around (e.g., partially surround) the display area DA.

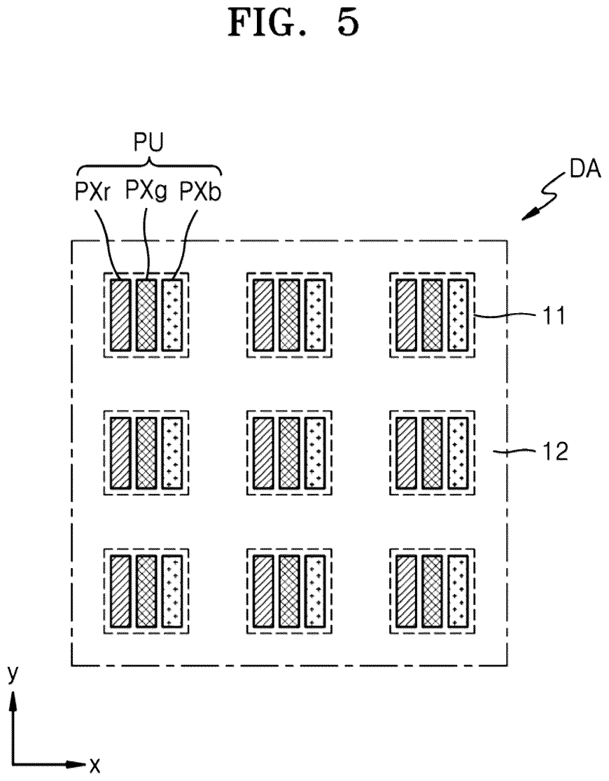

FIG. 5 is a schematic plan view of an arrangement of pixels of the display panel 10 according to an embodiment of the present disclosure.

Referring to FIG. 5, the display area DA may include first areas 11 and a second area 12 around (e.g., surrounding) each of the first areas 11. The first areas 11 may be repeatedly provided in the first direction (e.g., the x direction) and the second direction (e.g., the y direction).

The display area DA may include the first areas 11 and the second area 12 which have different elongations. For example, the display panel 10 may include the first area 11 having a relatively small elongation and the second area 12 having a relatively high elongation. In the specification, the elongation is a value representing a change (ΔL/L) in the length in which the display panel 10 is stretchable without a physical damage to the display panel 10 if (e.g., when) an external force is applied to the display panel 10. In embodiments, ΔL denotes a change in the length of the display panel 10, and L denotes the initial length of the display panel 10. Accordingly, the elongation of each of the first area 11 and the second area 12 may represent a change in the length of each of the first area 11 and the second area 12 if (e.g., when) the same external force is applied to the first area 11 and the second area 12.

That the elongation of the first area 11 is less than that of the second area 12 may indicate that the deformation of the first area 11 due to the external force is relatively small. Accordingly, the first area 11 may be referred to as a low deformation area, and the second area 12 may be referred to as a high deformation area.

The first areas 11 may be spaced apart from each other, and provided two dimensionally in the display area DA. The first area 11 may be an area where pixels are provided, and thus, the first area 11 may be referred to as a pixel area or an emission area. One or more pixels may be provided in each of the first areas 11. A pixel unit PU provided as a set of pixels may be provided in the first area 11, and each pixel unit PU may include a red pixel PXr, a green pixel PXg, and a blue pixel PXb.

The second area 12 may be between adjacent first areas 11. As illustrated in FIG. 5, in a plan view, the second area 12 may have a shape around (e.g., surrounding) each of the first areas 11. The second area 12 may be an area through which a connection line for electrically connecting pixel circuits (PC in FIG. 4) which are provided respectively in two adjacent first areas 11.

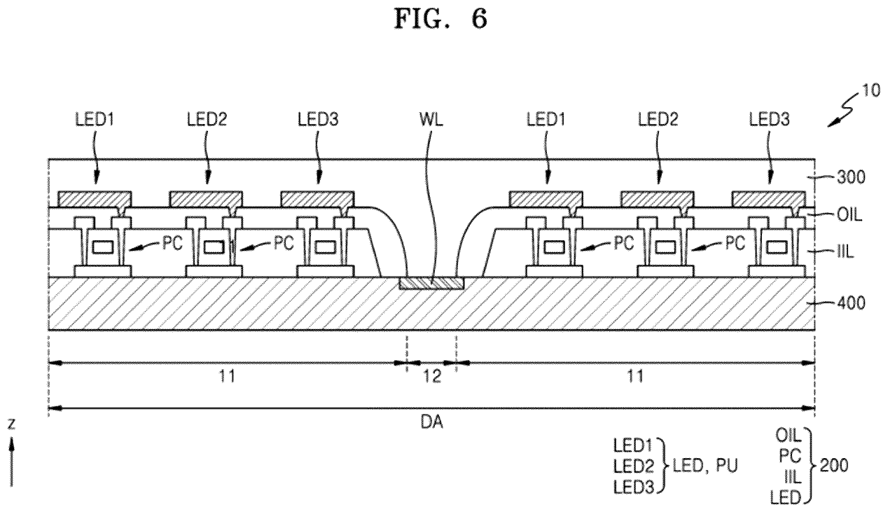

FIG. 6 is a cross-sectional view schematically showing a portion of the display panel 10 according to an embodiment of the present disclosure.

Referring to FIG. 6, the display area DA may include the first areas 11 and the second area 12, and the second area 12 may be an area that connects the first areas 11 that are provided adjacent to each other. The first area 11 is an area having an elongation that is relatively small compared with that of the second area 12, and may include a light-emitting diode LED and a pixel circuit PC. The second area 12, which is an area with elongation that is relatively high compared with that of the first area 11, may include a connection line WL included in a signal line through which a signal is supplied to each of the pixel circuits PC.

The first area 11 and the second area 12 may be on or formed on a base layer 400. In embodiments, the base layer 400 may define each of the first area 11 and the second area 12. The light-emitting diode LED and the pixel circuit PC may be provided in the first area 11 of the base layer 400, and the connection line WL may be provided in the second area 12 of the base layer 400.

The base layer 400 may absorb stress that may be generated during the elongation of the display panel 10. The base layer 400 may include elastic polymer. For example, the base layer 400 may include at least one selected from thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex.

A display layer 200 may be provided in the first area 11 of the base layer 400. The display layer 200 may include an inorganic insulating layer IIL (e.g., an inorganic electrically insulating layer), the pixel circuit PC, an organic insulating layer OIL (e.g., an organic electrically insulating layer), and the light-emitting diode LED. The pixel circuit PC may be on the base layer 400, and the inorganic insulating layer IIL may be between electrodes included in the pixel circuit PC. The organic insulating layer OIL may be on the inorganic insulating layer IIL to cover the pixel circuit PC. The light-emitting diode LED may be on the organic insulating layer OIL, and may be electrically connected to a corresponding pixel circuit PC. The inorganic insulating layer IIL may include an inorganic insulating material (e.g., an inorganic electrically insulating layer) such as silicon nitride and/or silicon oxide, and the organic insulating layer OIL may include an organic insulating material (e.g., an organic electrically insulating layer) such as polyimide.

In an embodiment, one pixel unit PU may be provided in one first area 11. The pixel unit PU may include, as described above, a red pixel (PXr in FIG. 5), a green pixel (PXg in FIG. 5), and a blue pixel (PXb in FIG. 5). The red pixel (PXr in FIG. 5A) may include a first light-emitting diode LED1, the green pixel (PXg in FIG. 5A) may include a second light-emitting diode LED2, and the blue pixel PXb may include a third light-emitting diode LED3. For example, the first light-emitting diode LED1 may emit red light, the second light-emitting diode LED2 may emit green light, and the third light-emitting diode LED3 may emit blue light. In some embodiments, the light-emitting diode LED may emit white light.

The connection line WL may be arranged in the second area 12 of the base layer 400. In an embodiment, as shown in FIG. 6, the connection line WL may be on the base layer 400, and may be provided relatively lower than the display layer 200. In embodiments, the base layer 400 may be provided to cover the connection line WL on the back surface of the display layer 200. Accordingly, the thickness of the base layer 400 corresponding to the second area 12 may be less than the thickness of the base layer 400 corresponding to the first area 11. However, the present disclosure is not limited thereto, and in another embodiment, the connection line WL may be on the base layer 400, for example, on substantially the same layer as a set or certain layer of the display layer 200.

The connection line WL may include a material having both excellent stretchability and electrical properties. In an embodiment, the plurality of connection lines WL provided in the second area 12 may include liquid metal. In another embodiment, the plurality of connection lines may include a metal nano structure and elastic polymer. In another embodiment, the plurality of connection lines may include a conductive composite material (e.g., an electrically conductive composite material) including elastomer.

In an embodiment, a protective layer 300 may be on the light-emitting diode LED. The protective layer 300 may be provided in both of the first area 11 and the second area 12. In embodiments, the protective layer 300 may be provided to entirely cover the display area DA. The protective layer 300 may cover the light-emitting diode LED and the connection line WL. The protective layer 300 may absorb stress that may be generated during the elongation of the display panel 10. In more detail, the protective layer 300 may prevent or reduce transmission of the stress that may be generated during the elongation of the display panel 10 to the light-emitting diode LED and the pixel circuit PC.

The protective layer 300 may include elastic polymer. The protective layer 300 may include at least one selected from thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and polydimethylsiloxane (PDMS). In an embodiment, the protective layer 300 may include the same material as the base layer 400. However, the present disclosure is not limited thereto, and the protective layer 300 may include a different material from that of the base layer 400.

FIGS. 7A to 7C are each an equivalent circuit diagram of a pixel of the display panel 10 according to an embodiment of the present disclosure.

Referring to FIG. 7A, the light-emitting diode LED corresponding to a pixel may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include a gate line (GL in FIG. 4) such as a scan signal line GWL, and a data line DL, and the voltage line may include a first voltage line VDDL. In embodiments, the first voltage line VDDL may be connected to the driving voltage supply wire (W11 in FIG. 4), and a second voltage line VSSL may be connected to the common voltage supply wire (W13 in FIG. 4).

The second transistor T2 may be electrically connected to the scan signal line GWL and the data line DL. The scan signal line GWL may be configured to provide a scan signal GW to a gate electrode of the second transistor T2. The second transistor T2 may transmit a data signal Dm input through the data line DL to the first transistor T1, in response to the scan signal GW input through the scan signal line GWL.

The storage capacitor Cst may be electrically connected to the second transistor T2 and the first voltage line VDDL, and may store a voltage corresponding to a difference between the voltage transmitted from the second transistor T2 and a first power voltage VDD received through the first voltage line VDDL.

The first transistor T1, as a driving transistor, may control a driving current that flows in the light-emitting diode LED. The first transistor T1 may be connected to the first voltage line VDDL and the storage capacitor Cst. The first transistor T1 may control the driving current that flows from the first voltage line VDDL to the light-emitting diode LED, in response to a voltage value stored in the storage capacitor Cst. The light-emitting diode LED may emit light having a set or certain luminance depending on the driving current. A first electrode of the light-emitting diode LED may be electrically connected to the first transistor T1, and a second electrode of the light-emitting diode LED may be electrically connected to the second voltage line VSSL through which a second power voltage VSS is supplied.

FIG. 7A illustrates that the pixel circuit PC includes two transistors and one storage capacitor, but in another embodiment, the pixel circuit PC may include three or more transistors.

Referring to FIG. 7B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC electrically connected to a plurality of signal lines and a plurality of voltage lines. The plurality of signal lines may include the scan signal line GWL, a bypass control line GBL, an initialization control line GIL, a gate line GL (see FIG. 4) such as an emission control line EML, and the data line DL. The plurality of voltage lines may include first and second initialization voltage lines VIL1 and VIL2 and the first voltage line VDDL. In embodiments, the first voltage line VDDL may be connected to the driving voltage supply wire (W11 in FIG. 4), and the second voltage line VSSL may be connected to the common voltage supply wire (W13 in FIG. 4).

The first voltage line VDDL may be configured to transmit the first power voltage VDD to the first transistor T1. The first initialization voltage line VIL1 may be configured to transmit a first initialization voltage Vint for initializing the first transistor T1 to the pixel circuit PC. The second initialization voltage line VIL2 may be configured to transmit a second initialization voltage Vaint to initialize a first electrode of the light-emitting diode LED, to the pixel circuit PC.

The first transistor T1 may be electrically connected to the first voltage line VDDL via the fifth transistor T5, and to the light-emitting diode LED via the sixth transistor T6. The first transistor T1, which serves as a driving transistor, may receive the data signal Dm according to a switching operation of the second transistor T2 and supply a driving current to the light-emitting diode LED.

The second transistor T2, as a data write transistor, may be electrically connected to the scan signal line GWL and the data line DL. The second transistor T2 may be electrically connected to the first voltage line VDDL via the fifth transistor T5. The second transistor T2 may be turned on in response to the scan signal GW received through the scan signal line GWL to perform a switching operation of to transmit the data signal Dm received through the data line DL to a first node N1.

The third transistor T3 may be electrically connected to the scan signal line GWL and electrically connected to the light-emitting diode LED via the sixth transistor T6. The third transistor T3 may be turned on in response to the scan signal GW received through the scan signal line GWL to be diode-connected to the first transistor T1.

The fourth transistor T4, as a first initialization transistor, may be electrically connected to the initialization control line GIL and the first initialization voltage line VIL1. The fourth transistor T4 may be turned on in response to an initialization control signal GI received through the initialization control line GIL to transmit the first initialization voltage Vint received through the first initialization voltage line VIL1 to a gate electrode of the first transistor T1, to thereby initialize the voltage of the gate electrode of the first transistor T1. The initialization control signal GI may correspond to a scan signal of another pixel circuit provided in the previous row of the corresponding pixel circuit PC.

The fifth transistor T5 may be an operation control transistor, and the sixth transistor T6 may be an emission control transistor. The fifth transistor T5 and the sixth transistor T6 may be electrically connected to the emission control line EML, and may be concurrently (e.g., simultaneously) turned on in response to an emission control signal EM received through the emission control line EML to form a current path (e.g., an electric current path) through which a driving current flows in a direction from the first voltage line VDDL to the light-emitting diode LED.

The seventh transistor T7, as a second initialization transistor, may be electrically connected to the bypass control line GBL, the second initialization voltage line VIL2, and the sixth transistor T6. The seventh transistor T7 may be turned on in response to a bypass control signal GB received through the bypass control line GBL, and may transmit the second initialization voltage Vaint through the second initialization voltage line VIL2 to the first electrode of the light-emitting diode LED, to thereby initialize the first electrode of the light-emitting diode LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and retain a voltage corresponding to a difference in voltage between opposite ends of the first voltage line VDDL and the gate electrode of the first transistor T1, to thereby retain the voltage applied to the gate electrode of the first transistor T1.

Referring to FIG. 7C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC may be electrically connected to the plurality of signal lines and the plurality of voltage lines. The plurality of signal lines may include the scan signal line GWL, the bypass control line GBL, the initialization control line GIL, the gate line (GL in FIG. 4) such as the emission control line EML, and the data line DL. The plurality of voltage lines may include the first and second initialization voltage lines VIL1 and VIL2, a sustain voltage line VSL, and the first voltage line VDDL. In embodiments, the first voltage line VDDL may be connected to the driving voltage supply wire (W11 in FIG. 4), and the second voltage line VSSL may be connected to the common voltage supply wire (W13 in FIG. 4).

The first voltage line VDDL may be configured to transmit the first power voltage VDD to the first transistor T1. The first initialization voltage line VIL1 may be configured to transmit the first initialization voltage Vint to initialize the first transistor T1 to the pixel circuit PC. The second initialization voltage line VIL2 may be configured to transmit the second initialization voltage Vaint to initialize the first electrode of the light-emitting diode LED to the pixel circuit PC. The sustain voltage line VSL may be configured to provide a sustain voltage VSUS to a second node N2, for example, the second electrode CE2 of the storage capacitor Cst, in an initialization section and a data write section.

The first transistor T1 may be electrically connected to the first voltage line VDDL via the fifth transistor T5 and the eighth transistor T8, and to the light-emitting diode LED via the sixth transistor T6. The first transistor T1, which serves as a driving transistor, may receive the data signal Dm according to the switching operation of the second transistor T2, and supply a driving current to the light-emitting diode LED.

The second transistor T2 may be electrically connected to the scan signal line GWL and the data line DL, and to the first voltage line VDDL via the fifth transistor T5 and the eighth transistor T8. The second transistor T2 may be turned on in response to the scan signal GW received through the scan signal line GWL to perform a switching operation of transmitting the data signal Dm received through the data line DL to the first node N1.

The third transistor T3 may be electrically connected to the scan signal line GWL, and to the light-emitting diode LED via the sixth transistor T6. The third transistor T3 may be turned on in response to the scan signal GW received through the scan signal line GWL to be diode-connected to the first transistor T1, to thereby compensate for a threshold voltage of the first transistor T1.

The fourth transistor T4 may be electrically connected to the initialization control line GIL and the first initialization voltage line VIL1, and may be turned on in response to the initialization control signal GI received through the initialization control line GIL to transmit the first initialization voltage Vint received through the first initialization voltage line VIL1 to the gate electrode of the first transistor T1, to thereby initialize the voltage of the gate electrode of the first transistor T1. The initialization control signal GI may correspond to a scan signal of another pixel circuit provided in the previous row of the corresponding pixel circuit PC.

The fifth transistor T5, the sixth transistor T6, and the eighth transistor T8 may be electrically connected to the emission control line EML, and may be concurrently (e.g., simultaneously) turned on in response to the emission control signal EM received through the emission control line EML to form a current path (e.g., an electric current path) through which a driving current flows in a direction from the first voltage line VDDL to the light-emitting diode LED.

The seventh transistor T7, as a second initialization transistor, may be electrically connected to the bypass control line GBL, the second initialization voltage line VIL2, and the sixth transistor T6. The seventh transistor T7 may be turned on in response to the bypass control signal GB received through the bypass control line GBL, and may transmit the second initialization voltage Vaint through the second initialization voltage line VIL2 to the first electrode of the light-emitting diode LED, to thereby initialize the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 may be turned on in response to the bypass control signal GB received through the bypass control line GBL, and may transmit the sustain voltage VSUS to the second node N2, for example, the second electrode CE2 of the storage capacitor Cst, in the initialization section and the data write section.

The eighth transistor T8 and the ninth transistor T9 may each be electrically connected to the second node N2, for example, the second electrode CE2 of the storage capacitor Cst. In some embodiments, in the initialization section and the data write section, the eighth transistor T8 may be turned off and the ninth transistor T9 may be turned on, and in a light-emitting section, the eighth transistor T8 may be turned on and the ninth transistor T9 may be turned off. As the sustain voltage VSUS is transmitted to the second node N2 in the initialization section and the data write section, uniformity (e.g., long range uniformity (LRU)) of luminance of the display device according to the voltage drop of the first voltage line VDDL may be improved.

The storage capacitor Cst may include the first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VSL, and the first electrode of the light-emitting diode LED. While the seventh transistor T7 and the ninth transistor T9 are turned on, the auxiliary capacitor Ca may store and retain a voltage corresponding to a difference in voltage between the first electrode of the light-emitting diode LED and the sustain voltage line VSL, thereby preventing or reducing an increase of black luminance if (e.g., when) the sixth transistor T6 is turned off.

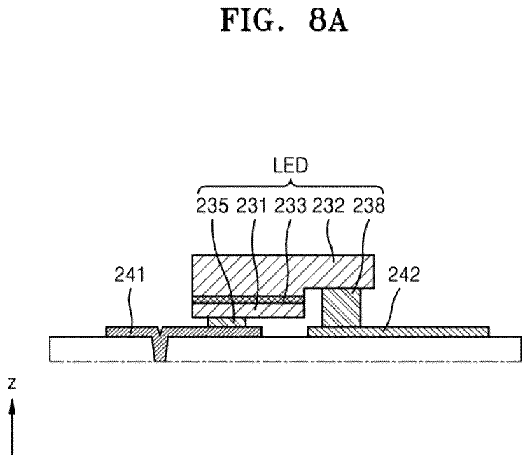

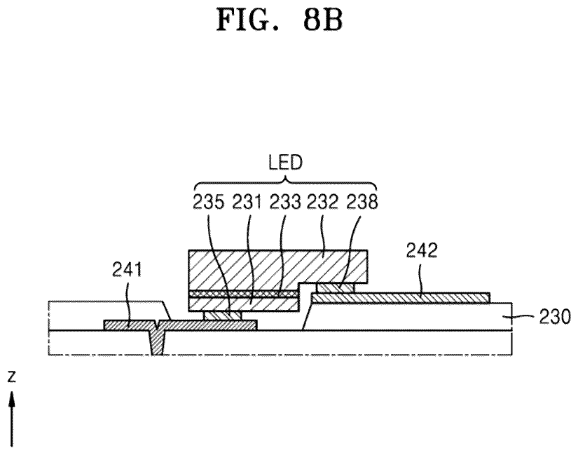

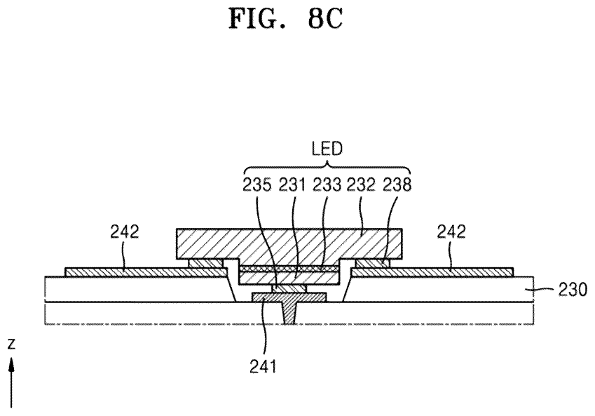

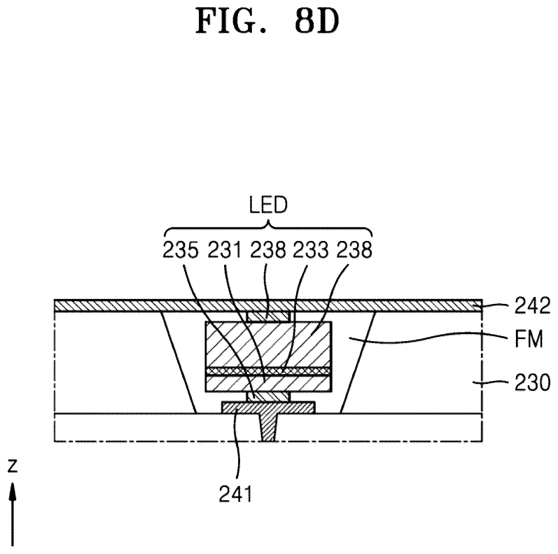

FIGS. 8A to 8D are each a cross-sectional view schematically showing a light-emitting diode of the display panel 10 according to an embodiment of the present disclosure.

Referring to FIG. 8A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 242 provided in a same layer. The second electrode pad 242 may be a part of the second voltage line VSSL (see FIG. 7A) or may be a conductive layer (e.g., an electrically conductive layer) electrically connected to the second voltage line VSSL (see FIG. 7A).

In some embodiments, the first semiconductor layer 231 may include a p-type semiconductor layer. The p-type semiconductor layer may be selected from semiconductor materials having a composition of InₓAl_{y}Ga_{1-x-y}N (0≤x≤1, 0≤y≤1, and 0≤(x+y)≤1), for example, GaN, AlN, AlGaN, InGaN, InN, InAlGaN, AlInN, and/or the like, and may be doped with a p-type dopant, such as Mg, Zn, Ca, Sr, Ba, and/or the like.

The second semiconductor layer 232 may include, for example, an n-type semiconductor layer. The n-type semiconductor layer may be selected from semiconductor materials having a composition of InₓAl_{y}Ga_{1-x-y}N (0≤x≤1, 0≤y≤1, and 0≤(x+y)≤1), for example, GaN, AlN, AlGaN, InGaN, InN, InAlGaN, AlInN, etc., and may be doped with an n-type dopant, such as Si, Ge, Sn, and/or the like.

The intermediate layer 233 is a region where electrons and holes recombine, and as electrons and holes recombine, the electrons and holes may transition to a lower energy level and may generate light having a corresponding wavelength. The intermediate layer 233 may include a semiconductor material having a composition, for example, inₓAl_{y}Ga_{1-x-y}N (0≤x≤1, 0≤y≤1, and 0≤(x+y)≤1), and may be formed in a single quantum well structure or a multi-quantum well (MQW) structure. Furthermore, the intermediate layer 233 may have a quantum wire structure and/or a quantum dot structure.

FIG. 8A illustrates that the first semiconductor layer 231 includes a p-type semiconductor layer, and that the second semiconductor layer 232 includes an n-type semiconductor layer, but the present disclosure is not limited thereto. In another embodiment, the first semiconductor layer 231 may include an n-type semiconductor layer, and the second semiconductor layer 232 may include a p-type semiconductor layer.

FIG. 8A illustrates that the first electrode pad 241 and the second electrode pad 242 are provided in the same layer, but the present disclosure is not limited thereto. Referring to FIG. 8B, the first electrode pad 241 and the second electrode pad 242 may be provided in different layers. For example, a bank layer 230 having an opening that overlaps at least a part of the first electrode pad 241 may be on the first electrode pad 241, and the second electrode pad 242 may be on an upper surface of the bank layer 230. The structure of the light-emitting diode LED illustrated in FIG. 8B is the same as the structure described above with reference to FIG. 8A.

In another embodiment, as illustrated in FIG. 8C, the second electrode pad 242 may be on the opposite sides of the first electrode pad 241, in a cross-sectional view. The bank layer 230 may include an opening that overlaps at least a part of the first electrode pad 241, and the second electrode pad 242 may be provided around the opening of the bank layer 230. In some embodiments, in a plan view, the second electrode pad 242 may have a closed loop shape that entirely surrounds the opening of the bank layer 230 and/or the first electrode pad 241. The structure of the light-emitting diode LED illustrated in FIG. 8C is the same as the structure described above with reference to FIG. 8A.

FIGS. 8A to 8C illustrate that the first electrode 235 and the second electrode 238 of the light-emitting diode LED face the same direction (e.g., a downward direction, for example, the −z direction), but the present disclosure is not limited thereto. As illustrated in FIG. 8D, the first electrode 235 and the second electrode 238 of the light-emitting diode LED may face opposite directions from each other.

The bank layer 230 may include an opening that exposes at least a part of the first electrode pad 241, and the thickness of the bank layer 230 may be substantially the same as the thickness of the light-emitting diode LED. The opening of the bank layer 230 may be filled with a filling material FM, and the second electrode pad 242 may be on the upper surface of the bank layer 230 so as to be electrically connected to (e.g., in contact with) the second electrode 238 of the light-emitting diode LED. The filling material FM may be an organic material having insulating properties (e.g., electrically insulating properties).

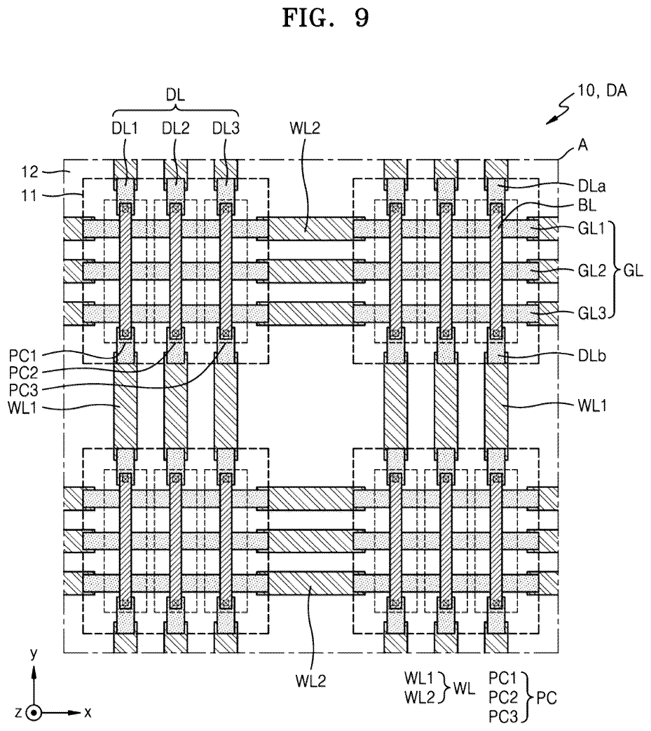

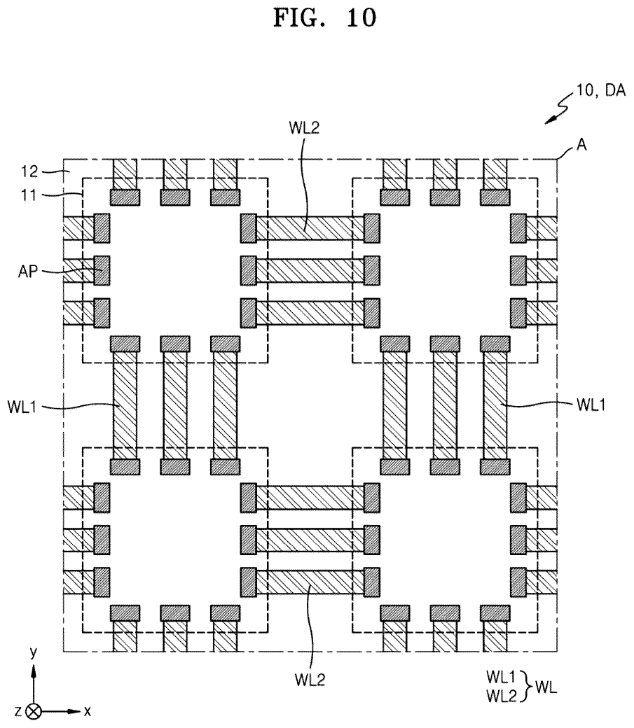

FIG. 9 is a schematic plan view of a portion of the display panel 10 according to an embodiment of the present disclosure. FIG. 10 is a plan view schematically showing a portion of the display panel 10 according to an embodiment of the present disclosure. FIGS. 9 and 10 are each a plan view schematically illustrating region A of the display panel 10 of FIG. 4. FIG. 9 is a plan view schematically illustrating a portion of the front surface of the display panel 10 according to an embodiment of the present disclosure, and FIG. 10 is a plan view schematically illustrating a portion of the back surface of the display panel 10 according to an embodiment of the present disclosure.

First, referring to FIG. 9, the display area DA may include the first areas 11 and the second area 12 around (e.g., surrounding) the first areas 11. The first areas 11 may have a greater elongation than that of the second area 12. Accordingly, if (e.g., when) the display panel 10 is stretched, the first area 11 may be less deformed than the second area 12. The first area 11 may be referred to as a low deformation area (or low deformation portion) as described above. Furthermore, the first area 11, which is an area where light-emitting diodes are provided, may be referred to as a pixel area or an emission area.

The second area 12 may be around (e.g., surround) the first area 11 and have a higher elongation than that of the first area 11. The second area 12 may be an area where major deformation occurs due to the stretch of the display device. The second area 12 may be between the first areas 11, and may be referred to as a connection portion that connects the first areas 11. Furthermore, the second area 12 may be referred to as a main deformation area (or a main deformation portion) or a high deformation area (or a high deformation portion). The second area 12, which is an area of the display area DA where light-emitting diodes are not provided, may be referred to as a non-pixel area or a non-emission area.

The pixel circuit PC to drive the light-emitting diode LED of each pixel may be on the first area 11. For example, a first pixel circuit PC1 of the red pixel (PXr in FIG. 5), a second pixel circuit PC2 of the green pixel (PXg in FIG. 5), and a third pixel circuit PC3 of the blue pixel PXb (see FIG. 5) may be provided in the first area 11. The first pixel circuit PC1, the second pixel circuit PC2, and the third pixel circuit PC3 may each include a transistor and a capacitor as in the pixel circuit PC described with reference to FIGS. 7A to 7C.

The plurality of lines electrically connected to the pixel circuit PC may be provided in the display area DA. The plurality of lines described above may include a voltage line and/or a signal line. In an embodiment, FIG. 7 illustrates that the gate line GL and the data line DL are each provided in the first area 11. The gate line GL and the data line DL may each be electrically connected to the pixel circuit PC through contact holes.

The gate line GL of FIG. 9 may be a line to provide a gate signal to the gate electrode of a transistor. In an embodiment, the gate line GL may include a first gate line GL1, a second gate line GL2, and a third gate line GL3. The first to third gate lines GL1, GL2, and GL3 that extend in the first direction (e.g., the x direction) may be connected to each of the pixel circuits PC provided in the same row to transmit different gate signals. For example, the gate line GL of FIG. 9 may be the scan signal line GWL, the bypass control line GBL, the initialization control line GIL, and/or the emission control line EML of FIG. 7B or 7C.

The data line DL of FIG. 9 is a line to provide a data signal to each pixel circuit PC. The data line DL that extends in the second direction (e.g., the y direction) may be electrically connected to the pixel circuits PC provided in the same column. In an embodiment, the data line DL may include a first data line DL1 electrically connected to the first pixel circuit PC1, a second data line DL2 electrically connected to the second pixel circuit PC2, and a third data line DL3 electrically connected to the third pixel circuit PC3.

Two adjacent signal lines respectively provided in two adjacent first areas 11 may be electrically connected to each other by the connection line WL. In more detail, two adjacent data lines DL respectively provided in two adjacent first areas 11 may be electrically connected to each other by a first connection line WL1 (or a vertical connection line). The first connection line WL1 may be provided in the second area 12 and may extend in the second direction (e.g., the y direction). Each of the plurality of data lines DL on the opposite sides with respect to the first connection line WL1 may be connected to the first connection line WL1.

Two adjacent gate lines GL respectively provided in two adjacent first areas 11 may be electrically connected to each other by a second connection line WL2 (or a horizontal connection line). The second connection line WL2 may be provided in the second area 12 and may extend in the first direction (e.g., the x direction). Each of the plurality of gate lines GL on the opposite sides with respect to the second connection line WL2 may be connected to the second connection line WL2.

The gate line GL and the data line DL may cross each other in the first area 11. In an embodiment, the data line DL may include a first part DLa and a second part DLb, which are separated from each other with the gate line GL therebetween, and a bridge line BL between the first part DLa and the second part DLb. The first part DLa and the second part DLb may be electrically connected to each other by the bridge line BL.

The bridge line BL may be provided in an area where the data line DL and the gate line GL cross each other, and may connect the first part DLa and the second part DLb of the data line DL to each other. The bridge line BL may be on a different layer from a layer where the first part DLa and the second part DLb are provided. One end of the bridge line BL may be connected to the first part DLa through a contact hole, and the other end of the bridge line BL may be connected to the second part DLb through another contact hole.

FIG. 9 illustrates that the data line DL connects through the first part DLa, the second part DLb, and the bridge line BL, but the present disclosure is not limited thereto. In another embodiment, the gate line GL may be separated into a first part and a second part, and both parts may be connected to each other through a bridge line.

The first and second connection lines WL1 and WL2 provided in the second area 12 may be stretched better than the gate line GL and the data line DL provided in the first area 11. The elongation of each of the first and second connection lines WL1 and WL2 may be greater than the elongation of each of the gate line GL and the data line DL.

The gate line GL and the data line DL may each include one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, the gate line GL and the data line DL may each be a single layer or a plurality of layers including the metal described above. In an embodiment, the gate line GL and the data line DL may each include a metal thin film included or formed in a triple layer of a titanium (Ti)/aluminum (Al)/titanium (Ti) structure.

The first and second connection lines WL1 and WL2 may include liquid metal, and/or a metal nano structure, elastic polymer, and/or a conductive composite material (e.g., an electrically conductive composite material) including elastomer. Accordingly, if (e.g., when) the display panel 10 is stretched, high deformation may occur in the first and second connection lines WL1 and WL2 and the second area 12.

FIG. 9 illustrates that the gate line GL and the data line DL are electrically connected to the second connection line WL2 and the first connection line WL1, respectively, but the present disclosure is not limited thereto. In another embodiment, a first initialization voltage line VIL1, a second initialization voltage line VIL2, a sustain voltage line VSL, the first voltage line VDDL, and/or the second voltage line VSSL, which is described with reference to FIGS. 7A to 7C, may each be provided in the first area 11 and may be electrically connected to the connection line WL provided in the second area 12.

Next, FIG. 10 is a schematic plan view illustrating a partial area of the display area DA viewed in a back surface direction of the display panel 10. In embodiments, an auxiliary pattern AP may be provided to cover both ends of the connection line WL. In embodiments, as the end portion of the connection line WL is fixed to the auxiliary pattern AP, the display panel 10 may have a shape in which the end portion of the connection line WL is stuck in the auxiliary pattern AP. In embodiments, the auxiliary pattern AP may have a shape that caps the edge of the connection line WL.

In an embodiment, a plurality of auxiliary patterns AP may be spaced apart from each other in one first area 11. As illustrated in FIG. 10, end portions of the plurality of connection lines WL may be provided in one first area 11. For example, the end portions of the plurality of first connection lines WL1 and the end portions of the plurality of second connection lines WL2 may be provided in the first area 11. In embodiments, the end portions of the plurality of connection lines WL and the auxiliary pattern AP may be provided in the first area 11, and portions of the plurality of connection lines WL, excluding the end portions, may be provided in the second area 12. In embodiments, the plurality of auxiliary patterns AP may be spaced apart from each other while covering the end portion of each of the connection lines WL. In an embodiment, the auxiliary patterns AP may each have a quadrangular shape in a plan view. However, the present disclosure is not limited thereto, and the auxiliary patterns AP may have a polygonal shape other than a quadrangle.

In an embodiment, the modulus of the auxiliary pattern AP may be greater than the modulus of the connection line WL. In more detail, the modulus of the auxiliary pattern AP may have a value in a range of 10 times to 5000 times the modulus of the connection line WL. For example, the auxiliary pattern AP may include a material including nanocomposite. However, the material of the auxiliary pattern AP is not limited thereto, and the auxiliary pattern AP may include another material having a modulus in the above range.

Generally, the larger the modulus of a material, the better the recovery rate, and the smaller the modulus of a material, the better the elongation. As in an embodiment of the present disclosure, if (e.g., when) the auxiliary pattern AP has a relatively large modulus compared with the connection line WL, the auxiliary pattern AP may exhibit stiffness and recovery rate superior to the connection line WL, and the connection line WL may exhibit stretchability superior to the auxiliary pattern AP.

As described above, if (e.g., when) the display panel 10 is stretched, relatively high deformation may occur in the second area 12 compared with the first area 11. Accordingly, stress may be concentrated on the end portion of the connection line WL that is on a boundary between the first area 11 and the second area 12. In embodiments, if (e.g., when) the auxiliary pattern AP having a large modulus is provided to cover the end portion of the connection line WL, the auxiliary pattern AP may reduce the stress concentrated on the end portion of the connection line WL, and minimize or reduce the deformation of the first area 11 that may occur during stretching, thereby securing stability of a device. In embodiments, in the display panel 10 according to an embodiment of the present disclosure, as the auxiliary pattern AP having a large modulus is provided at the end portion of the connection line WL, stretchability and mechanical stability of the display panel 10 may be concurrently (e.g., simultaneously) implemented.

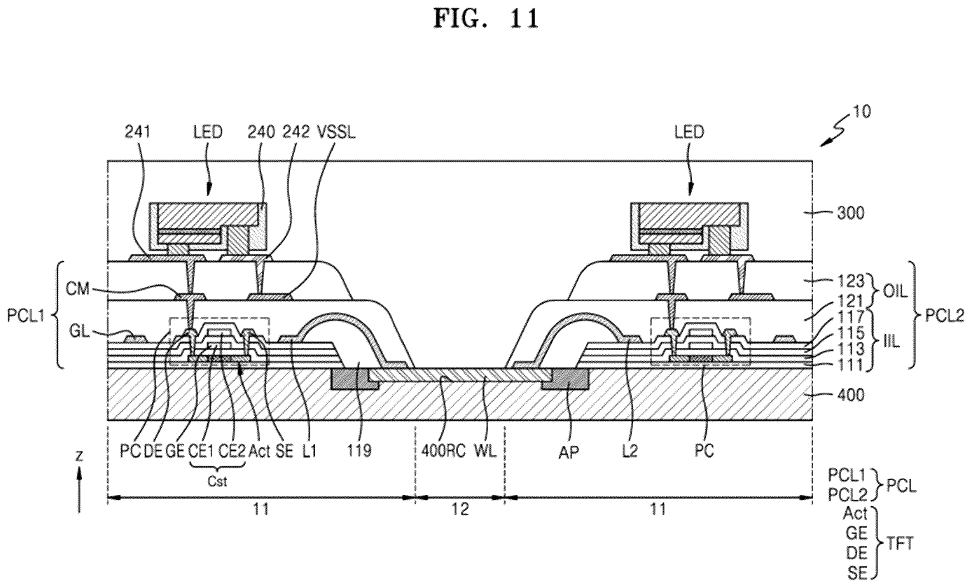

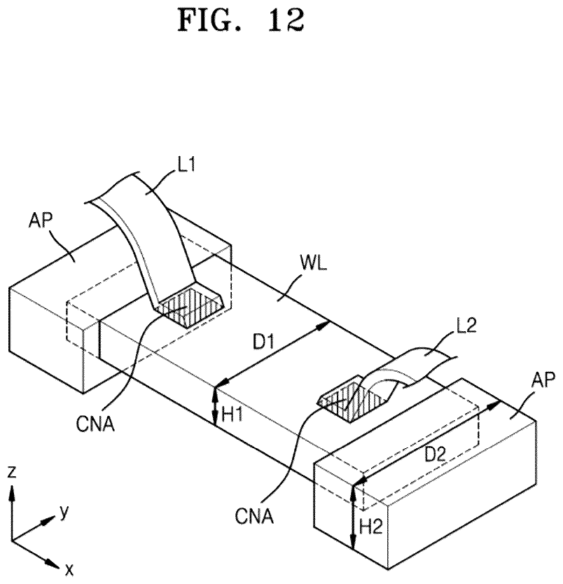

FIG. 11 is a cross-sectional view schematically showing a portion of the display panel 10 according to an embodiment of the present disclosure. FIG. 12 is a perspective view showing an excerpt of a first line, a second line, a connection line, and an auxiliary pattern of FIG. 11.

Referring to FIG. 11, as described above with reference to FIGS. 9 and 10, the display panel 10 may include the first areas 11 and the second area 12 between the first areas 11. As the components of the display panel 10 are on the base layer 400, that the display panel 10 includes the first areas 11 and the second area 12 may correspond to that the base layer 400 includes the first areas 11 and the second area 12.

The display panel 10 may include a pixel circuit layer PCL provided in each of two adjacent first areas 11 and the light-emitting diode LED on the pixel circuit layer PCL. The light-emitting diode LED illustrated in FIG. 11 may correspond to any one selected from the first to third light-emitting diodes LED1, LED2, and LED3 illustrated in FIG. 6.

Each pixel circuit layer PCL may include an inorganic insulating stack IIL (e.g., an inorganic electrically insulating stack), the pixel circuit PC, and the organic insulating layer OIL (e.g., an organic electrically insulating stack). In the following description, for convenience of explanation, one of the pixel circuit layers PCL respectively provided in the two adjacent first areas 11 is referred to as a first pixel circuit layer PCL1, and the other is referred to as a second pixel circuit layer PCL2.

The first pixel circuit layer PCL1 and the second pixel circuit layer PCL2 may each be on the base layer 400. The first pixel circuit layer PCL1 and the second pixel circuit layer PCL2 may each be on a first surface (e.g., an upper surface) of the base layer 400.

The base layer 400 may absorb stress that is generated during the elongation of the display panel 10. The base layer 400 may include elastic polymer. The base layer 400 may include at least one selected from thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex.

The first pixel circuit layer PCL1 and the second pixel circuit layer PCL2 may each include the inorganic insulating stack IIL, the pixel circuit PC, and the organic insulating layer OIL. The inorganic insulating stack IIL may include a buffer layer 111, a gate insulating layer 113, a first interlayer insulating layer 115, and a second interlayer insulating layer 117. The organic insulating layer OIL may include a first organic insulating layer 121 and a second organic insulating layer 123.

The first pixel circuit layer PCL1 and the second pixel circuit layer PCL2 may be spaced apart from each other. That the first pixel circuit layer PCL1 and the second pixel circuit layer PCL2 are spaced apart from each other means that the inorganic insulating stack IIL, the pixel circuit PC, and the organic insulating layer OIL of the first pixel circuit layer PCL1 are respectively spaced apart from the inorganic insulating stack IIL, the pixel circuit PC, and the organic insulating layer OIL of the second pixel circuit layer PCL2.

The inorganic insulating stack IIL may be provided in the first area 11 and may not be provided in the second area 12. The inorganic insulating stack IIL may have an isolated shape provided in the first area 11. The inorganic insulating stack IIL provided in each of the first areas 11 may be apart from each other in a plan view. For example, the buffer layer 111, the gate insulating layer 113, the first interlayer insulating layer 115, and the second interlayer insulating layer 117 of the first pixel circuit layer PCL1 may be respectively separated from the buffer layer 111, the gate insulating layer 113, the first interlayer insulating layer 115, and the second interlayer insulating layer 117 of the second pixel circuit layer PCL2.

In embodiments, the organic insulating layer OIL may be provided in the first area 11 and may not be provided in the second area 12. The organic insulating layer OIL may have an isolated shape provided in the first area 11. For example, the first organic insulating layer 121 and the second organic insulating layer 123 of the first pixel circuit layer PCL1 may be respectively separated from the first organic insulating layer 121 and the second organic insulating layer 123 of the second pixel circuit layer PCL2.

As illustrated in FIG. 11, the buffer layer 111 may be on the base layer 400, and the pixel circuit PC may be on the buffer layer 111. The buffer layer 111 may include an inorganic insulating material (e.g., an inorganic electrically insulating material), such as silicon oxide, silicon nitride, and/or silicon oxynitride.

A thin film transistor TFT of the pixel circuit PC may include a semiconductor layer Act, a gate electrode GE, a source electrode SE, and a drain electrode DE. FIG. 11 illustrates a top gate type or kind in which the gate electrode GE is on the semiconductor layer Act with the gate insulating layer 113 therebetween, but according to another embodiment, the thin film transistor TFT may be of a bottom gate type or kind.

The semiconductor layer Act may include polysilicon. In embodiments, the semiconductor layer Act may include amorphous silicon, oxide semiconductor, organic semiconductor, and/or the like. The gate electrode GE may include a metal thin film including a low resistance (e.g., low electrical resistance) metal material. The gate electrode GE may include a conductive material (e.g., an electrically conductive material) including molybdenum (Mo), aluminum (Al), copper (Cu), titanium (Ti), and/or the like, and may be formed in a multilayer or single layer including the material described above. For example, the gate electrode GE may include a metal thin film formed in a triple layer structure of titanium (Ti)/aluminum (Al)/titanium (Ti).

The gate insulating layer 113 between the semiconductor layer Act and the gate electrode GE may include an inorganic insulating material (e.g., an inorganic electrically insulating material), such as silicon oxide, nitrogen oxide, silicon oxynitride, aluminum oxide, and/or titanium oxide. The gate insulating layer 113 may be a single layer or multilayer including the material described above.

The source electrode SE and the drain electrode DE may be on the same layer, for example, the second interlayer insulating layer 117, and may include the same material. The source electrode SE and the drain electrode DE may include a metal thin film including a low resistance (e.g., a low electrical resistance) metal material. The source electrode SE and the drain electrode DE may include a conductive material (e.g., an electrically conductive material) including molybdenum (Mo), aluminum (Al), copper (Cu), titanium (Ti), and/or the like, and may be formed in a multilayer or single layer including the material described above. For example, the source electrode SE and the drain electrode DE, like the gate electrode GE, may be provided as a metal thin film formed in a triple layer structure of titanium (Ti)/aluminum (Al)/titanium (Ti). The second interlayer insulating layer 117 may include an inorganic insulating material (e.g., an inorganic electrically insulating material), such as silicon oxide, nitrogen oxide, silicon oxynitride, aluminum oxide, and/or titanium oxide, and may be a single layer or multilayer including the material described above.

A storage capacitor Cst may include a first electrode CE1 and a second electrode CE2 that overlap each other with the first interlayer insulating layer 115 therebetween. The storage capacitor Cst may be overlapped with the thin film transistor TFT. In this connection, FIG. 7 illustrates that the gate electrode GE of the thin film transistor TFT is the first electrode CE1 of the storage capacitor Cst. In another embodiment, the storage capacitor Cst may not be overlapped with the thin film transistor TFT. The storage capacitor Cst may be covered with the second interlayer insulating layer 117.

The first interlayer insulating layer 115 may be between the gate insulating layer 113 and the second interlayer insulating layer 117. The first interlayer insulating layer 115 and the second interlayer insulating layer 117 may each include an inorganic insulating material (e.g., an inorganic electrically insulating material), such as silicon oxide, nitrogen oxide, silicon oxynitride, aluminum oxide, and/or titanium oxide, and may be a single layer or multilayer including the material described above.

The second electrode CE2 of the storage capacitor Cst may include a conductive material (e.g., an electrically conductive material), and may be formed in a multilayer or single layer. The second electrode CE2 may include a metal thin film including a low resistance (e.g., a low electrical resistance) metal material. The second electrode CE2 may include a conductive material (e.g., an electrically conductive material) including molybdenum (Mo), aluminum (Al), copper (Cu), titanium (Ti), and/or the like, and may be formed in a multilayer or single layer including the material described above. For example, the second electrode CE2 may be provided as a metal thin film formed in a triple layer structure of titanium (Ti)/aluminum (Al)/titanium (Ti).

The first organic insulating layer 121 may be on the second interlayer insulating layer 117. The second organic insulating layer 123 may be on the first organic insulating layer 121. A connection electrode CM and the second voltage line VSSL may be on the first organic insulating layer 121. The connection electrode CM may electrically connect the pixel circuit PC to a first electrode pad 241. The second voltage line VSSL may be electrically connected to a second electrode pad 242.

The connection electrode CM and the second voltage line VSSL may include a metal thin film including a low resistance (e.g., a low electrical resistance) metal material. The connection electrode CM and the second voltage line VSSL may include a conductive material (e.g., an electrically conductive material) including molybdenum (Mo), aluminum (Al), copper (Cu), titanium (Ti), and/or the like, and may be formed in a multilayer or single layer including the material described above. For example, the connection electrode CM and the second voltage line VSSL may be provided as a metal thin film formed in a triple layer structure of titanium (Ti)/aluminum (Al)/titanium (Ti).

The first electrode pad 241 and the second electrode pad 242 may be on the second organic insulating layer 123. The first electrode pad 241 may be electrically connected to the thin film transistor TFT through the connection electrode CM between the first organic insulating layer 121 and the second organic insulating layer 123.

The light-emitting diode LED on the first electrode pad 241 and the second electrode pad 242 may be the same as the light-emitting diode LED described above with reference to FIG. 8A. In another embodiment, the light-emitting diode LED may have the same structure as that described with reference to FIGS. 8B to 8D. One surface of the light-emitting diode LED may be covered with a protective layer 240 including an organic insulating material (e.g., an organic electrically insulating material).

A first line L1 may be a signal line or voltage line which is electrically connected to the pixel circuit PC of the first pixel circuit layer PCL1. A second line L2 may be a signal line or voltage line which is electrically connected to the pixel circuit PC of the second pixel circuit layer PCL2. In an embodiment, the first line L1 and the second line L2 may include the gate line (GL in FIG. 9) or the data line (DL in FIG. 9) described above with reference to FIG. 9. In another embodiment, the first line L1 and the second line L2 may be the first voltage line VDDL or the second voltage line VSSL, which is described with reference to FIG. 7A, or the first initialization voltage line VIL1, the second initialization voltage line VIL2, the sustain voltage line VSL, the first voltage line VDDL, or the second voltage line VSSL, which are described with reference to FIG. 7B and FIG. 7C.

Each of the first line L1 and the second line L2 may be on the second interlayer insulating layer 117, and may extend to the connection line WL. A portion of the first line L1 may be on a corresponding second interlayer insulating layer 117. The other portion of the first line L1 may extend to the connection line WL by passing the inorganic insulating stack IIL, and may be in direct contact with the connection line WL. In the third direction (e.g., the z direction), the portion of the first line L1 may be between the second interlayer insulating layer 117 and the first organic insulating layer 121, and the other portion of the first line L1 may be between a third organic insulating layer 119 to be described below and the second organic insulating layer 123. In embodiments, a portion of the second line L2 may be on a corresponding second interlayer insulating layer 117, and the other portion of the second line L2 may extend to the connection line WL and may be in direct contact with the connection line WL. In the third direction (e.g., the z direction), the portion of the second line L2 may be between the second interlayer insulating layer 117 and the first organic insulating layer 121, and the other portion of the second line L2 may be between the third organic insulating layer 119 to be described below and the second organic insulating layer 123.

The inorganic insulating stack IIL having an isolated shape in a plan view may form a step with respect to the upper surface of the base layer 400, as illustrated in FIG. 11. In an embodiment, as illustrated in FIG. 11, the organic insulating layer OIL may further include the third organic insulating layer 119 that is provided to cover a side surface of the inorganic insulating stack IIL. The third organic insulating layer 119 may have a closed loop shape in a plan view to cover the side surface of the inorganic insulating stack IIL. The first line L1 and the second line L2 may extend to the connection line WL by passing the upper surface of a corresponding third organic insulating layer 119.

As described above, the connection line WL may be provided in the second area 12. In an embodiment, the connection line WL may be on a bottom surface of the pixel circuit layer PCL. In embodiments, the base layer 400 may include a recess 400RC that is concave from an upper surface toward a lower surface, and the connection line WL may be present in the recess 400RC.

The connection line WL may include a first surface (e.g., a lower surface) toward the base layer 400 and a second surface (e.g., an upper surface) that is opposite to the first surface. The second surface (e.g., the upper surface) of the connection line WL may be on the same surface as the upper surface of the base layer 400. Accordingly, the thickness of a portion of the base layer 400 that overlaps the connection line WL may be less than the thickness of the other portion of the base layer 400 that does not overlap the connection line WL. In embodiments, as the connection line WL has a structure of being embedded in the base layer 400, the stress that may be concentrated on the connection line WL during the elongation of the display panel 10 may be absorbed by the base layer 400.

In an embodiment, the auxiliary pattern AP may be on both end portions of the connection line WL. The auxiliary pattern AP may have a shape that caps the edge of the connection line WL. As described above, the modulus of the auxiliary pattern AP may have a value in a range of 10 times to 5000 times the modulus of the connection line WL. Accordingly, the auxiliary pattern AP may reduce strain that may be concentrated on both end portions of the connection line WL.

The auxiliary pattern AP, like the connection line WL, may have a structure of being embedded in the base layer 400. In embodiments, the auxiliary pattern AP may be on the bottom surface of the pixel circuit layer PCL. The base layer 400 may cover a lower surface of the connection line WL and a lower surface of the auxiliary pattern AP. The volume of the recess 400RC of the base layer 400 may be substantially the same as the sum of the volume of the connection line WL and the volume of the auxiliary pattern AP.

Referring to FIG. 12, the auxiliary pattern AP may be on each of both end portions of the connection line WL, and the first line L1 and the second line L2 may each extend to the connection line WL so as to be in direct contact with the upper surface of the connection line WL. A contact area CAN of the first line L1 and the connection line WL may be the same as an area of a bottom surface of a portion of the first line L1 that meets the upper surface of the connection line WL. A contact area CAN of the second line L2 and the connection line WL may be the same as an area of a bottom surface of a portion of the second line L2 that meets the upper surface of the connection line WL.

With respect to the third direction (e.g., the z direction), the connection line WL may have a first thickness H1, and the auxiliary pattern AP may have a second thickness H2. In an embodiment, the second thickness H2 of the auxiliary pattern AP may be greater than the first thickness H1 of the connection line WL. In more detail, the second thickness H2 of the auxiliary pattern AP may be 1.25 times or more the first thickness H1 of the connection line WL.

Furthermore, with respect to the second direction (e.g., the y direction), the connection line WL may have a first width D1, and the auxiliary pattern AP may have a second width D2. In an embodiment, the second width D2 of the auxiliary pattern AP may be greater than the first width D1 of the connection line WL. In more detail, the second width D2 of the auxiliary pattern AP may be 1.25 times or more the first width D1 of the connection line WL.

In embodiments, the area of the side surface of the auxiliary pattern AP that faces the connection line WL may be larger than the area of the side surface of the connection line WL facing the auxiliary pattern AP. As described above, if (e.g., when) the side surface of the auxiliary pattern AP is formed to be larger than the side surface of the connection line WL, as the auxiliary pattern AP may have a shape around (e.g., surrounding) the end portion of the connection line WL, the auxiliary pattern AP may efficiently reduce the strain applied to the end portion of the connection line WL.

Referring back to FIG. 11, the light-emitting diode LED may be on a corresponding pixel circuit layer PCL. For example, the light-emitting diode LED electrically connected to the pixel circuit PC of the first pixel circuit layer PCL1 may be on a corresponding first pixel circuit layer PCL1, and the light-emitting diode LED electrically connected to the pixel circuit PC of the second pixel circuit layer PCL2 may be on a corresponding second pixel circuit layer PCL2. One surface of each light-emitting diode LED may be covered with the protective layer 240. The protective layer 240 may include an organic insulating material (e.g., an organic electrically insulating material) such as polyimide.

The protective layer 300 may be on the light-emitting diode LED and the connection line WL. The protective layer 300 may cover the light-emitting diode LED and the connection line WL. The protective layer 300 may absorb the stress that may be transmitted to the light-emitting diode LED and the connection line WL during the elongation of the display panel 10, and may planarize the upper surface of the display panel 10. The protective layer 300 may include elastic polymer. For example, the protective layer 300 may include at least one selected from thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex.

The protective layer 300 may be in direct contact with the upper surface of the connection line WL, and may be in direct contact with a portion of the upper surface of the base layer 400. In an embodiment, if (e.g., when) the material of the protective layer 300 and the material of the base layer 400 are same as each other, the bonding strength of the protective layer 300 and the base layer 400 may be increased, thereby more effectively maintaining the airtight seal of the display panel 10.

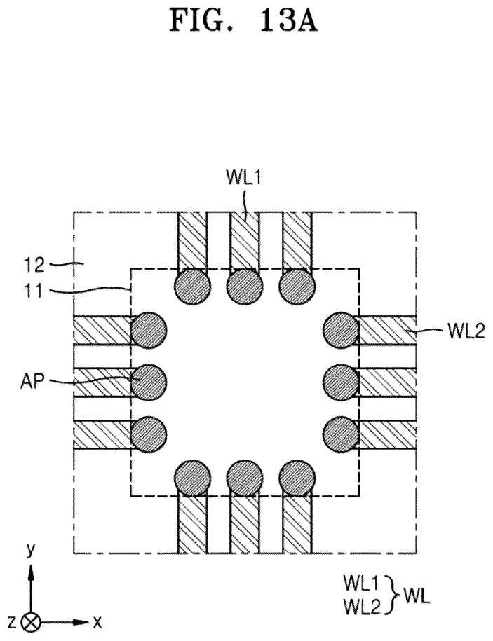

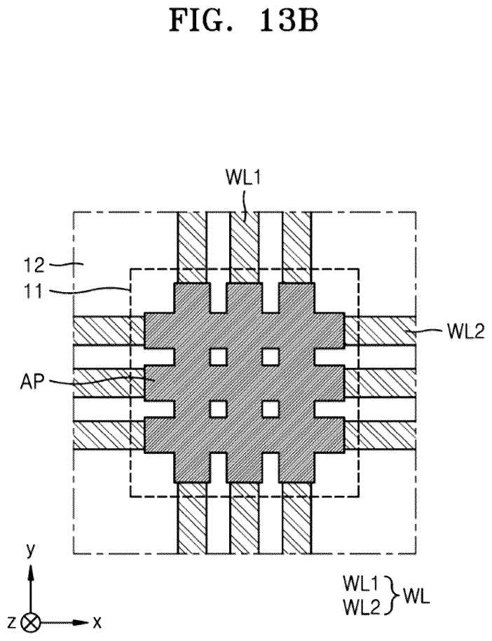

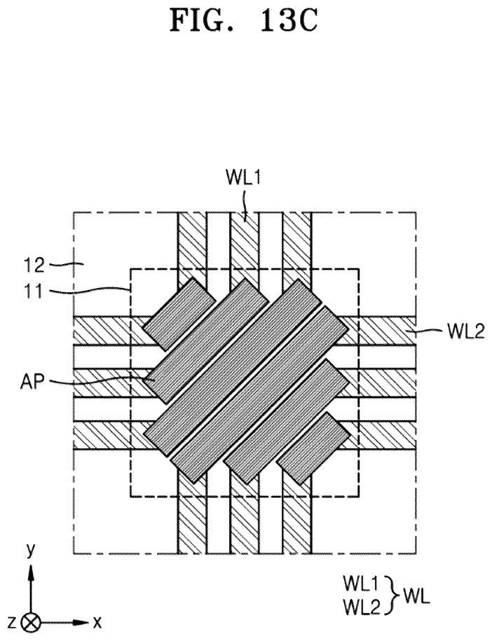

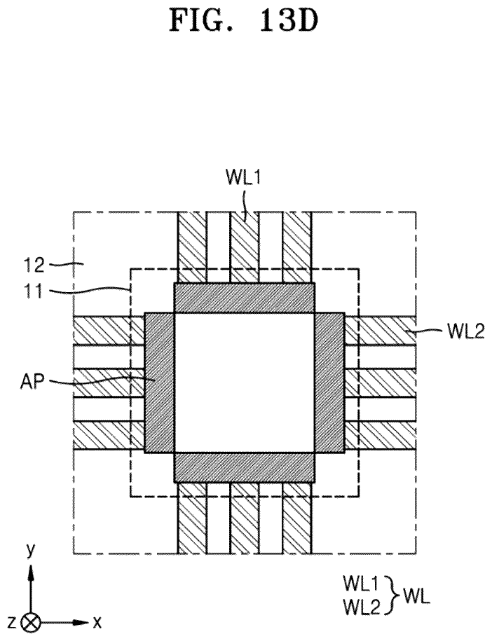

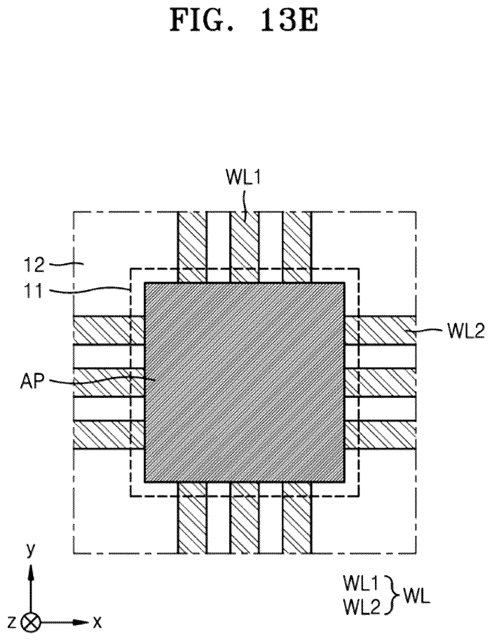

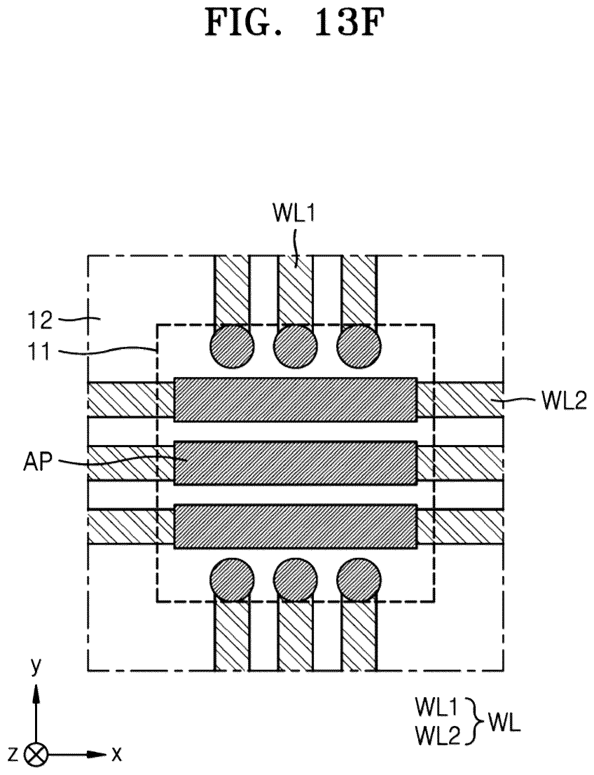

FIGS. 13A to 13F are each a plan view schematically showing a portion of the display panel 10 according to embodiments of the present disclosure. Referring to FIGS. 13A to 13G, except for the features of the auxiliary pattern AP, the other features are the same as those described with reference to FIGS. 9 to 11. The descriptions of the same reference numerals of elements in FIGS. 13A to 13G are replaced with those presented above with reference to FIGS. 9 to 11, and in the following description, differences are mainly described.

First, referring to FIG. 13A, the auxiliary pattern AP may be provided to cover the end portion of the connection line WL. In an embodiment, in one first area 11, the plurality of auxiliary patterns AP may be spaced apart from each other. In embodiments, the plurality of auxiliary patterns AP may respectively cover the end portions of the plurality of connection lines WL, and may be spaced apart from each other. In an embodiment, the auxiliary patterns AP may each have a circular shape (e.g., a generally circular shape) in a plan view. However, the present disclosure is not limited thereto, and the auxiliary patterns AP may each have an oval shape (e.g., a generally oval shape).

Next, referring to FIG. 13B, the auxiliary pattern AP may be provided to cover the end portion of the connection line WL. However, in one first area 11, one auxiliary pattern AP to cover the end portions of each of the plurality of connection lines WL may be provided. For example, one auxiliary pattern AP may extend in the second direction (e.g., the y direction) to cover the end portions of the first connection line (WL1, or the vertical connection line), and one auxiliary pattern AP may extend in the first direction (e.g., the x direction) to cover the end portions of the second connection line (WL2, or the horizontal connection line). In embodiments, the auxiliary pattern AP may have a mesh pattern in the first area 11, in a plan view.

Next, referring to FIG. 13C, the auxiliary pattern AP may be provided to cover the end portion of the connection line WL. In embodiments, one auxiliary pattern AP may be provided to cover the end portions of two or more connection lines WL among the plurality of connection lines WL. For example, one auxiliary pattern AP may extend in a diagonal direction between the first direction (e.g., the x direction) and the second direction (e.g., the y direction). One end of the auxiliary pattern AP extending in the diagonal direction may cover the end portion of one first connection line (WL1, or the vertical connection line), and the other end of the auxiliary pattern AP may cover the end portion of one second connection line (WL2, or the horizontal connection line). The plurality of auxiliary patterns AP each having the shape described above may be provided in the first area 11.

Next, referring to FIG. 13D, the auxiliary pattern AP may be provided to cover the end portion of the connection line WL. In embodiments, one auxiliary pattern AP may be provided to cover the end portions of two or more connection lines WL among the plurality of connection lines WL. For example, one auxiliary pattern AP may extend in the first direction (e.g., the x direction) or in the second direction (e.g., the y direction). One auxiliary pattern AP that extends in the first direction (e.g., the x direction) may cover the end portions of the plurality of first connection lines (WL1, or the vertical connection lines) on one side (e.g., an upper side or a lower side) of the first area 11. One auxiliary pattern AP that extends in the second direction (e.g., the y direction) may cover the end portions of the plurality of second connection lines (WL2, or the horizontal connection lines) on one side (e.g., a left side or a right side) of the first area 11. The plurality of auxiliary patterns AP each having the shape described above may be provided in the first area 11.

Next, referring to FIG. 13E, the auxiliary pattern AP may be provided to cover the end portion of the connection line WL. However, in one first area 11, one auxiliary pattern AP to cover the end portions of each of the plurality of connection lines WL may be provided. For example, one auxiliary pattern AP may have a single continuous shape to overlap the pixel circuit layer (PCL in FIG. 11) in a plan view. As illustrated in FIG. 13E, the auxiliary pattern AP may have a quadrangular shape having an area relatively smaller than the first area 11, and may be provided to overlap the pixel circuit layer (PCL in FIG. 11). As the auxiliary pattern AP has the shape described above, the auxiliary pattern AP may cover the end portions of all of the plurality of connection lines WL provided in the four sides of the first area 11. In embodiments, as one auxiliary pattern AP has an area expanded to fill the first area 11, the end portions of the plurality of first connection lines (WL1, or the vertical connection lines) and the end portions of the plurality of second connection lines (WL2, or the horizontal connection lines) may be all be covered.

Next, referring to FIG. 13F, the auxiliary pattern AP may be provided to cover the end portion of the connection line WL. While the plurality of auxiliary patterns AP are provided in the first area 11, some of the plurality of auxiliary patterns AP may cover the end portion of only one connection line WL, and the rest of the plurality of auxiliary patterns AP may cover the end portions of the plurality of connection lines WL. For example, some of the plurality of auxiliary patterns AP may be provided to cover the end portions of the first connection lines (WL1, or the vertical connection lines) while spaced apart from each other. While the rest of the plurality of auxiliary patterns AP may extend in the first direction (e.g., the x direction), one end of the auxiliary pattern AP may cover the end portion of the second connection line (WL2, or the horizontal connection line) on the left side of the first area 11, and the other end of the auxiliary pattern AP may cover the end portion of the second connection line (WL2, or the horizontal connection line) on the right side of the first area 11. However, the present disclosure is not limited thereto, and the arrangement and shapes of the plurality of auxiliary patterns AP may suitably vary depending on the plurality of connection lines WL.

As illustrated in FIGS. 13B to 13F, the auxiliary pattern AP may not only cover the end portion of only one connection line WL, but also cover the end portions of each of the plurality of connection lines WL. In an embodiment, if (e.g., when) the auxiliary pattern AP has a structure to cover the end portions of the plurality of connection lines WL as described above, the modulus of the auxiliary pattern AP may have a value in a range of 10 times to 500 times the modulus of the connection line WL. In embodiments, the auxiliary pattern AP that covers the end portions of the plurality of connection lines WL may have a modulus that is relatively smaller than that of the auxiliary pattern AP that covers the end portion of only one connection line WL, as illustrated in FIG. 10. However, even if (e.g., when) the modulus of the auxiliary pattern AP has a relatively small value, if (e.g., when) the auxiliary pattern AP covers the end portions of the plurality of connection lines WL, the volume of the auxiliary pattern AP increases so that the auxiliary pattern AP may efficiently reduce the strain applied to the end portion of the connection line WL. Accordingly, the display panel according to other embodiments of the present disclosure may concurrently (e.g., simultaneously) implement excellent stretchability and mechanical stability.

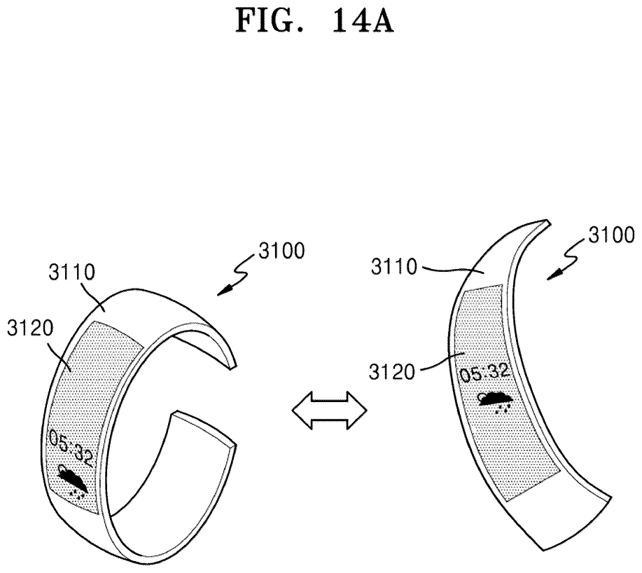

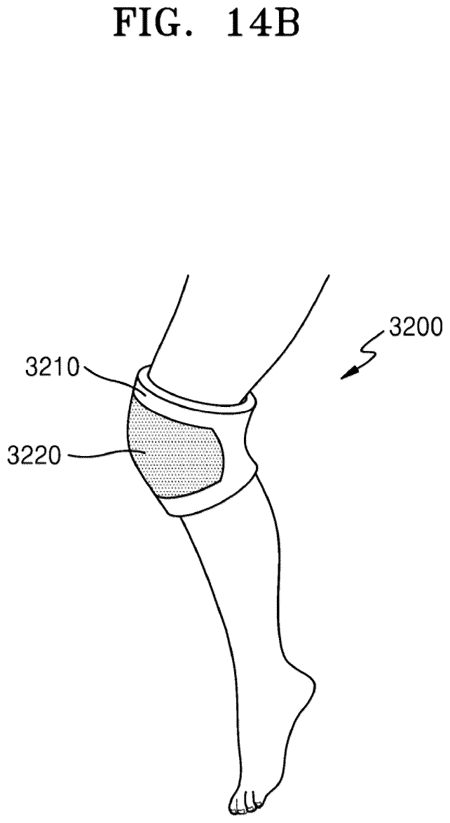

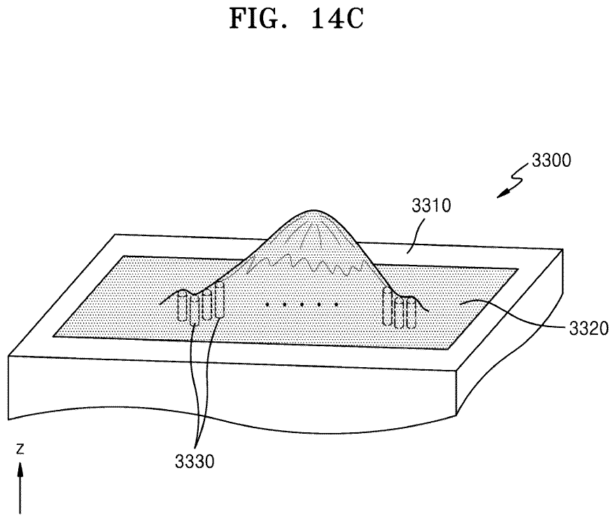

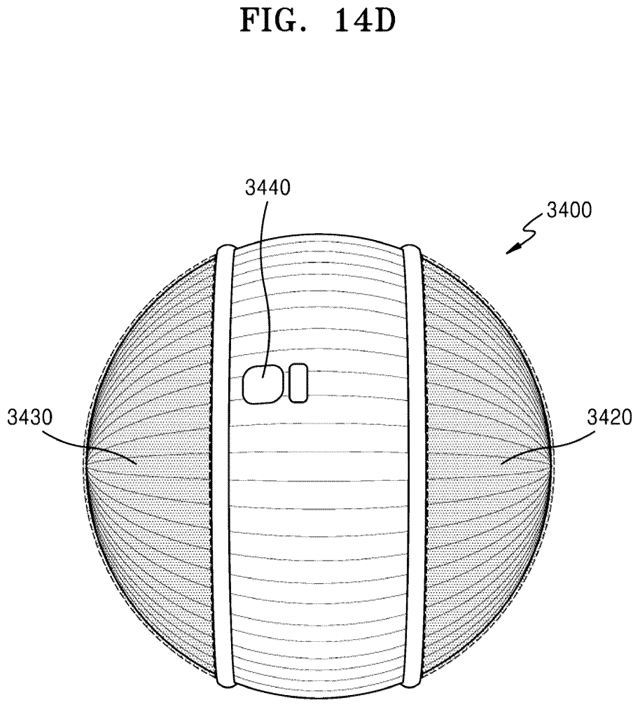

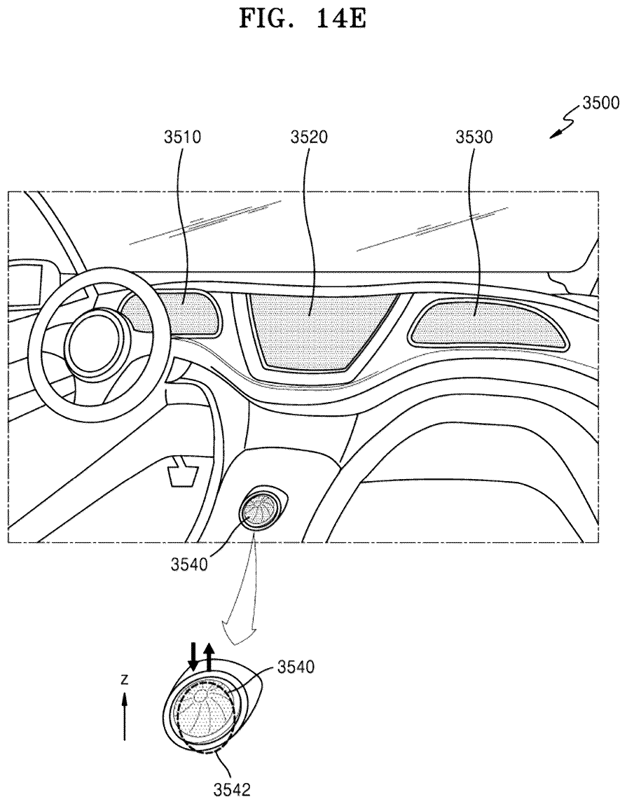

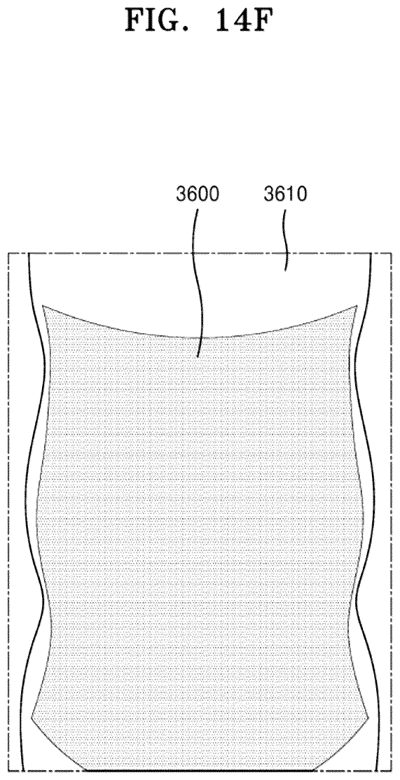

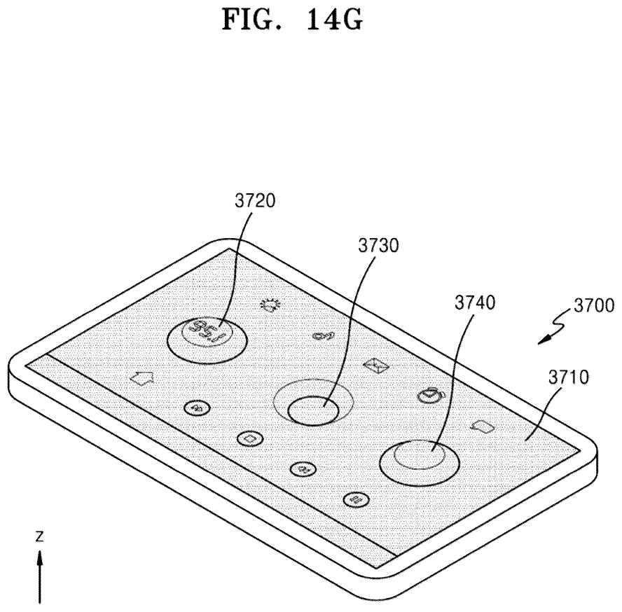

FIGS. 14A to 14G are each a perspective view schematically showing embodiments of an electronic device including a display panel according to an embodiment of the present disclosure.

Referring to FIG. 14A, the display panel according to the embodiments described above may be used for a wearable electronic device 3100 that is wearable in a part of a user′s body. The wearable electronic device 3100 may include a body part 3110 and a display part 3120 provided in the body part 3110. The display panel according to the embodiments described above may be used as the display part 3120 of the wearable electronic device 3100. As illustrated in FIG. 14A, the wearable electronic device 3100 may be deformable. In an embodiment, the wearable electronic device 3100 may be used as a smart watch and/or a smartphone according to the user's selection.

FIG. 14B illustrates a medical electronic device 3200. In an embodiment, the medical electronic device 3200 may include a body part 3210 and an emission unit 3220. The display panel according to the embodiments described above may be used as the emission unit 3220 of the medical electronic device 3200. The emission unit 3220 may emit light (e.g., infrared, visible light, and/or the like) of a set or certain wavelength band to the body of a patient. In an embodiment, the body part 3210 may include a stretchable textile material, and may have a structure to be worn on the body of a user using the emission unit 3220.

FIG. 14C illustrates an educational electronic device 3300. In an embodiment, the educational electronic device 3300 may include a display part 3320 provided in a frame 3310. The display part 3320 may use the display panel according to the embodiments described above. Images such as a sea with crashing waves, a snow-covered mountain, and/or a volcano with flowing lava may be provided through the display part 3320, and in embodiments, the display part 3320 may be stretched in a height direction (e.g., the z direction) by reflecting the height of the waves, the mountain, and/or the volcano. In some embodiments, a part of the display part 3320 has a height that sequentially and suitably varies depending on a direction in which lava flows, thereby showing the movement of lava in three dimensions. The educational electronic device 3300 may include a plurality of pins (and/or strokes parts 3330) on the rear surface of the display part 3320 to cause the display part 3320 to be stretched in the height direction. As the pins 3330 move in the third direction (e.g., the z direction or the −z direction), the image displayed in the display part 3320 may be implemented to have a height in three dimensions. Although FIG. 14C illustrates the educational electronic device 3300, any suitable device capable of providing set or certain image information may be limited by a use thereof.

The electronic devices described with reference to FIGS. 14A to 14C may have a suitably variable shape, but the present disclosure is not limited thereto. As in the embodiments described below, the display panel according to the embodiments described above may be used for electronic devices in which a part (e.g., a screen) to display an image is fixed.

FIG. 14D illustrates a robot 3400 as an electronic device according to an embodiment of the present disclosure. The robot 3400 may recognize a movement and/or an object by using a camera unit 3440, and display a set or certain image to a user through display parts 3420 and 3430. In some embodiments, as the display panel according to the embodiments of the present disclosure is stretchable in various suitable directions as described above, the display panel may be assembled to a body frame having a hemispherical shape, and thus, the robot 3400 may include the display parts 3420 and 3430 that are hemispherical.

FIG. 14E illustrates a vehicle display device 3500 as an electronic device according to an embodiment of the present disclosure. The vehicle display device 3500 may include a cluster 3510, a center information display (CID) 3520, and/or a passenger display. As the display panel according to the embodiment of the present disclosure is stretchable in various suitable directions, regardless of the shape of an internal frame of a vehicle, the display panel may be used for the cluster 3510, the CID 3520, and/or the co-driver display.

Although FIG. 14E illustrates that the cluster 3510, the CID 3520, and/or the co-driver display are separated from one another, the present disclosure is not limited thereto. In another embodiment, two or more components selected from among the cluster 3510, the CID 3520, and the co-driver display may be connected integrally.

In some embodiments, the vehicle display device 3500 may include a button 3540 that is capable of displaying a set or certain image. Referring to the enlarged portion of FIG. 14E, the button 3540 that is hemispherical may include an object 3542 that moves in the z direction or the −z direction and provides a sense of using a button and a display device above the object 3542. In some embodiments, if (e.g., when) the object 3542 has a three-dimensionally rounded surface, the display device may have a three dimensionally further rounded surface.

FIG. 14F illustrates that an electronic device according to an embodiment of the present disclosure is an electronic device 3600 to advertise and/or display. In some embodiments, the electronic device 3600 to advertise and/or display may be on a structure 3610 that is fixed, such as a wall and/or a pillar. If (e.g., when) the structure 3610 includes an uneven surface as illustrated in FIG. 14F, the electronic device 3600 to advertise and/or display may be provided along the uneven surface of the structure 3610. In some embodiments, the electronic device 3600 to advertise and/or display may be on the structure 3610 by using a heat shrink film and/or the like.

FIG. 14G illustrates that an electronic device according to an embodiment is a controller 3700. The controller 3700 may include an image type or kind button. For example, the controller 3700 may include first to third button areas 3720, 3730, and 3740 as partial areas of a display part 3710 protrude in the z direction or in the −z direction (or recessed in the z direction). In some embodiments, the first and third button areas 3720 and 3740 may protrude in the z direction, and the second button area 3730 may protrude in the −z direction (or recessed in the z direction).

While the subject matter of the present disclosure has been particularly shown and described with reference to example embodiments using example terminologies, the embodiments and terminologies should be considered in descriptive sense only and not for purposes of limitation. Therefore, it will be understood by those of ordinary skill in the art that various suitable changes in form and details may be made therein without departing from the spirit and scope of the present disclosure as defined by the following claims, and equivalents thereof.

### LIST OF REFERENCE NUMERALS FOR MAJOR ELEMENTS

1: electronic device
10: display panel
DA: display area
NDA: non-display area
PC: pixel circuit
LED: light-emitting diode
11: first area
12: second area
400: base layer
PCL: pixel circuit layer
300: protective layer
WL: connection line
AP: auxiliary pattern

What is claimed is:

1. A display panel comprising:
a plurality of first areas and a second area around each of the plurality of first areas, the display panel comprising:
a pixel circuit layer comprising a plurality of pixel circuits and insulating layers and provided in each of the plurality of first areas;
a plurality of light-emitting diodes on the pixel circuit layer and electrically connected to each of the plurality of pixel circuits;
a connection line that electrically connects pixel circuits provided adjacent to each other among the plurality of pixel circuits; and
an auxiliary pattern provided to cover both end portions of the connection line.

2. The display panel of claim 1, wherein:
the both end portions of the connection line and the auxiliary pattern are provided in one first area of the plurality of first areas,
a portion of the connection line, excluding the both end portions, is provided in the second area.

3. The display panel of claim 1, wherein:
a modulus of the auxiliary pattern is greater than a modulus of the connection line.

4. The display panel of claim 3, wherein:
the modulus of the auxiliary pattern has a value in a range of 10 times to 5000 times the modulus of the connection line.

5. The display panel of claim 1, further comprising:
a base layer under the pixel circuit layer and that covers a lower surface of the connection line and a lower surface of the auxiliary pattern.

6. The display panel of claim 1, wherein,
with respect to a thickness direction of the pixel circuit layer,
a thickness of the auxiliary pattern is greater than a thickness of the connection line.

7. The display panel of claim 6, wherein,
with respect to a thickness direction of the pixel circuit layer,
the thickness of the auxiliary pattern is 1.25 times or more the thickness of the connection line.

8. The display panel of claim 1, wherein:
the connection line extends in a first direction,
the connection line has a first width in a second direction that crosses the first direction,
the auxiliary pattern has a second width in the second direction, and
in a plan view, the second width of the auxiliary pattern is greater than the first width of the connection line.

9. The display panel of claim 8, wherein:
the second width of the auxiliary pattern is 1.25 times or more the first width of the connection line.

10. The display panel of claim 1, wherein:
the connection line comprises a plurality of connection lines,
pixel circuits provided in one first area of the plurality of first areas are connected to the plurality of connection lines,
the plurality of connection lines comprise a plurality of horizontal connection lines that extend in a first direction and a plurality of vertical connection lines that extend in a second direction crossing the first direction.

11. The display panel of claim 10, wherein:
the auxiliary pattern is provided in plurality to respectively cover end portions of the plurality of connection lines, and
the plurality of auxiliary patterns are spaced apart from each other.

12. The display panel of claim 10, wherein:
one auxiliary pattern covers end portions of two or more connection lines among the plurality of connection lines.

13. The display panel of claim 10, wherein:
one auxiliary pattern that covers all of end portions of the plurality of connection lines is provided in one first area among the plurality of first areas.

14. The display panel of claim 13, wherein:
the auxiliary pattern has a mesh pattern in the first area, in a plan view.

15. The display panel of claim 13, wherein:
the auxiliary pattern has a single continuous shape to overlap the pixel circuit layer in a plan view.

16. The display panel of claim 10, wherein:
the auxiliary pattern extends in the first area in a diagonal direction between the first direction and the second direction.

17. The display panel of claim 16, wherein:
one end of the auxiliary pattern covers an end portion of one of the plurality of horizontal connection lines, and another end of the auxiliary pattern covers an end portion of one of the plurality of vertical connection lines.

18. The display panel of claim 10, wherein:
the auxiliary pattern extends in the first direction or the second direction, and
covers end portions of the plurality of connection lines on one side of the first area.

19. The display panel of claim 10, wherein:
the auxiliary pattern is provided in a plurality,
some of the plurality of auxiliary patterns cover an end portion of one connection line among the plurality of connection lines, and
the rest of the plurality of auxiliary patterns cover end portions of two or more connection lines among the plurality of connection lines.

20. An electronic device comprising:
a display panel comprising a plurality of first areas and a second area around each of the plurality of first areas; and
a lower cover that forms an exterior and having, in a front surface, an opening that exposes a portion of the display panel,
wherein the display panel comprises:
a pixel circuit layer comprising a plurality of pixel circuits and insulating layers and provided in each of the plurality of first areas;
a plurality of light-emitting diodes on the pixel circuit layer and electrically connected to each of the plurality of pixel circuits;
a connection line that electrically connects pixel circuits provided adjacent to each other among the plurality of pixel circuits; and
an auxiliary pattern provided to cover both end portions of the connection line.
